(19) United States
(12) Patent Application Publication
(10) Pub. No.: US 2026/0045287 A1
(43) Pub. Date: Feb. 12, 2026

(54) MEMORY DEVICE AND OPERATING METHOD OF THE MEMORY DEVICE

(71) Applicant: Samsung Electronics Co., Ltd., Suwon-si (KR)

(72) Inventors: Soichiro MIZUSAKI, Suwon-si (KR); Kwangseok KIM, Suwon-si (KR); Jungsik PARK, Suwon-si (KR); Atsushi OKADA, Suwon-si (KR); Seungjae LEE, Suwon-si (KR); Unghwan PI, Suwon-si (KR); Naoki HASE, Suwon-si (KR)

(73) Assignee: Samsung Electronics Co., Ltd., Suwon-si (KR)

(21) Appl. No.: 19/016,755

(22) Filed: Jan. 10, 2025

(30) Foreign Application Priority Data
Aug. 7, 2024 (KR) 10-2024-0105748

(51) Int. Cl. G11C 11/16; H10B 61/00; H10N 50/01; H10N 50/10; H10N 50/85

(52) U.S. Cl. CPC G11C 11/161; H10B 61/20; H10N 50/01; H10N 50/10; H10N 50/85

(57) ABSTRACT

A memory device includes a heavy metal layer, a free layer on the heavy metal layer, a dielectric layer on the free layer, and a pinned layer and a volume change material layer on the dielectric layer and spaced apart from each other. The dielectric layer includes an oxide including magnesium (Mg).

### CROSS-REFERENCE TO RELATED APPLICATION

This application is based on and claims priority under 35 U.S.C. § 119 to Korean Patent Application No. 10-2024-0105748, filed on Aug. 7, 2024, in the Korean Intellectual Property Office, the disclosure of which is incorporated by reference herein in its entirety.

### BACKGROUND

Some example embodiments relate to a memory device and/or an operating method of the memory device.

A racetrack memory device uses a magnetic domain as a memory unit and stores information as logic ‘1’ and ‘0’ according to a direction of the magnetic domain. The racetrack memory device has a characteristic whereby a direction in which the magnetic domain moves within a racetrack changes according to a direction in which the current flows. The racetrack memory device is attracting attention as an ultra-fast and high-capacity memory device because a movement speed of magnetic domains is very fast and the size of the magnetic domain is small.

Methods of controlling the magnetic domain in the racetrack memory device include an Oersted magnetic field generation method and/or a spin orbit torque based driving method. However, the Oersted magnetic field generation method has disadvantages of requiring or using a large amount of additional current, of reducing writing power efficiency, and of being difficult to apply to a material with strong perpendicular magnetic anisotropy, while the spin orbit torque based driving method has a problem in that injection of an external magnetic field is required or used to break the symmetry of a spin polarization direction and a magnetization direction so as to control a direction of magnetization inversion of a free layer.

### SUMMARY

Some example embodiments provide a memory device capable of more easily injecting a magnetic domain into a racetrack (RT)-line, and/or an operating method of the memory device.

Additional aspects will be set forth in part in the description which follows and, in part, will be apparent from the description, and/or may be learned by practice of the presented embodiments of the disclosure.

According to some example embodiments, a memory device includes a heavy metal layer, a free layer on the heavy metal layer, a dielectric layer on the free layer, and a pinned layer and a volume change material layer on the dielectric layer and spaced apart from each other. The dielectric layer includes an oxide including magnesium (Mg).

The volume change material layer may include a ferroelectric material or a piezoelectric material.

The volume change material layer may include at least one of HfO₂, Hf₁₋ₓZrₓO₂(1<x<0), Hf₁₋ₓAlₓO₂(1<x<0), BaTiO₃, or PbZr₁₋ₓTiₓO₃(1<x<0).

The volume change material layer may include at least one of GaN, InN, AlN, BaTiO₃, PbZr₁₋ₓTiₓO₃(1<x<0), BiFeO₃, or ZnO.

The heavy metal layer may include at least one of iridium (Ir), ruthenium (Ru), tantalum (Ta), platinum (Pt), palladium (Pd), bismuth (Bi), titanium (Ti), tungsten (W), or an alloy thereof.

The free layer may include cobalt (Co).

The free layer may have a synthetic anti-ferromagnetic (SAF) structure.

The free layer may include a first ferromagnetic layer, a non-magnetic layer, and a second ferromagnetic layer which are sequentially stacked.

The first ferromagnetic layer may include CoNiCo, the non-magnetic layer may include Ru, and the second ferromagnetic layer may include CoFeB.

The memory device may further include a first electrode on the pinned layer.

The first electrode may include TiN or Au.

The memory device may further include a second electrode on the volume change material layer.

The electrode may include TiN.

The memory device may further include a third electrode and a fourth electrode spaced apart from each other on the free layer.

Alternatively or additionally according to some example embodiments, a memory device includes a heavy metal layer, a free layer on the heavy metal layer, a dielectric layer on the free layer, a pinned layer on the dielectric layer and corresponding to a magnetic tunnel junction (MTJ) structure with the free layer and the dielectric layer, and a plurality of volume change material layers on the dielectric layer and configured to inject magnetic domains into the free layer. The dielectric layer includes an oxide including magnesium (Mg).

The plurality of volume change material layers may each independently or concurrently include at least one of a ferroelectric material or a piezoelectric material.

The plurality of volume change material layers may each independently or concurrently include at least one of HfO₂, Hf₁₋ₓZrₓO₂, Hf₁₋ₓAlₓO₂, BaTiO₃, or PbZr₁₋ₓTiₓO₃(1<x<0).

The plurality of volume change material layers may each independently or concurrently include at least one of GaN, InN, AlN, BaTiO₃, PbZr₁₋ₓTiₓO₃(1<x<0), BiFeO₃, or ZnO.

The free layer may have a SAF structure.

Alternatively or additionally according to some example embodiments, an operating method of a memory device including a heavy metal layer, a free layer on the heavy metal layer, a dielectric layer on the free layer, including an oxide including magnesium (Mg), and arranged a racetrack (RT)-line with the heavy metal layer and the free layer, and a pinned layer and a volume change material layer on the dielectric layer and spaced apart from each other, the operating method includes initializing the RT-line, forming a magnetic domain in the free layer by applying a current to the volume change material layer, and reading the magnetic domain overlapping the pinned layer in a perpendicular direction.

### BRIEF DESCRIPTION OF THE DRAWINGS

The above and other aspects, features, and/or advantages of some example embodiments will be more apparent from the following description taken in conjunction with the accompanying drawings, in which:

FIG. 1 is a perspective view illustrating a memory device according to some example embodiments;

FIG. 2 is a cross-sectional view illustrating a part of the memory device of FIG. 1;

FIG. 3 is a diagram illustrating a device corresponding to a part A of FIG. 2;

FIG. 4 is a diagram illustrating a part of a device for describing an inverse magnetostrictive effect;

FIGS. 5A to 5G are diagrams illustrating a data writing method of a memory device, according to some example embodiments;

FIG. 6 is a diagram illustrating a free layer of a memory device according to some example embodiments;

FIGS. 7A to 7E are diagrams illustrating a data writing method of a memory device, according to some example embodiments;

FIGS. 8A to 8G are diagrams illustrating a data writing method of a memory device, according to some example embodiments;

FIGS. 9A to 9F are diagrams illustrating a data reading method of a memory device, according to some example embodiments;

FIGS. 10A to 10E are diagrams for describing a racetrack (RT)-line initializing method of a memory device, according to some example embodiments;

FIG. 11 is a perspective view illustrating a memory device according to some example embodiments;

FIGS. 12A to 12D are diagrams illustrating a data reading method of a memory device, according to some example embodiments;

FIGS. 12E and 12F are diagrams for describing a RT-line initializing method of a memory device, according to some example embodiments;

FIG. 13 is a flowchart illustrating an operating method of a memory device, according to some example embodiments;

FIG. 14 is a diagram illustrating a memory system according to some example embodiments; and

FIG. 15 is a conceptual diagram schematically illustrating a device architecture applicable to an electronic device, according to some example embodiments.

### DETAILED DESCRIPTION

Reference will now be made in detail to some embodiments, examples of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, with reference to the accompanying drawings, a memory device and an operating method of the memory device will be described in detail. Like reference numerals refer to like elements throughout, and in the drawings, sizes of elements may be exaggerated for clarity and convenience of explanation. The embodiments described below are merely exemplary, and various modifications may be possible from the embodiments.

In a layer structure described below, an expression “on” may include not only “immediately on in a contact manner” but also “on in a non-contact manner”. An expression used in the singular encompasses the expression of the plural unless it has a clearly different meaning in the context. It will be further understood that the terms “comprises” and/or “comprising” used herein specify the presence of stated features or elements, but do not preclude the presence or addition of one or more other features or elements.

The use of “the” and other demonstratives similar thereto may correspond to both a singular form and a plural form. Unless the order of operations of a method according to the disclosure is explicitly mentioned or described otherwise, the operations may be performed in a proper order. The disclosure is not limited to the order the operations are mentioned.

The connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language provided herein, is intended merely to better illuminate the disclosure and does not pose a limitation on the scope of the disclosure unless otherwise claimed.

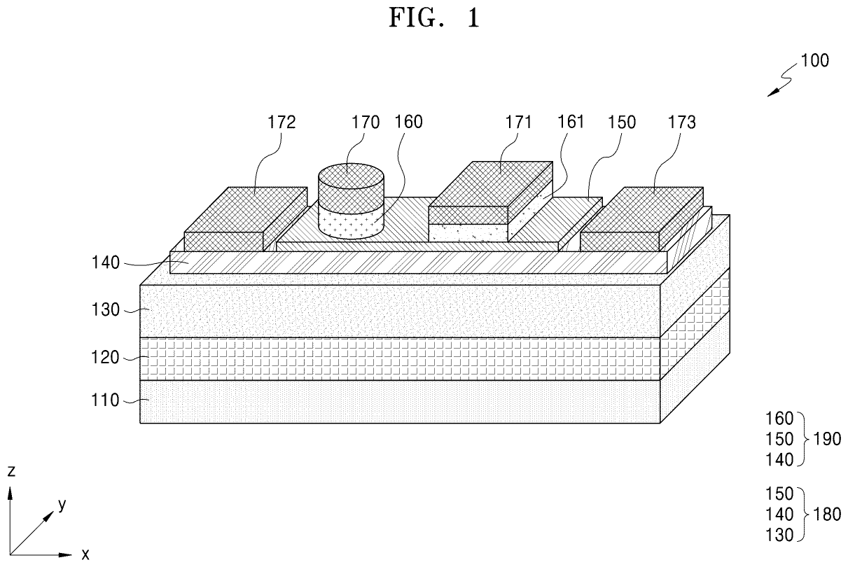

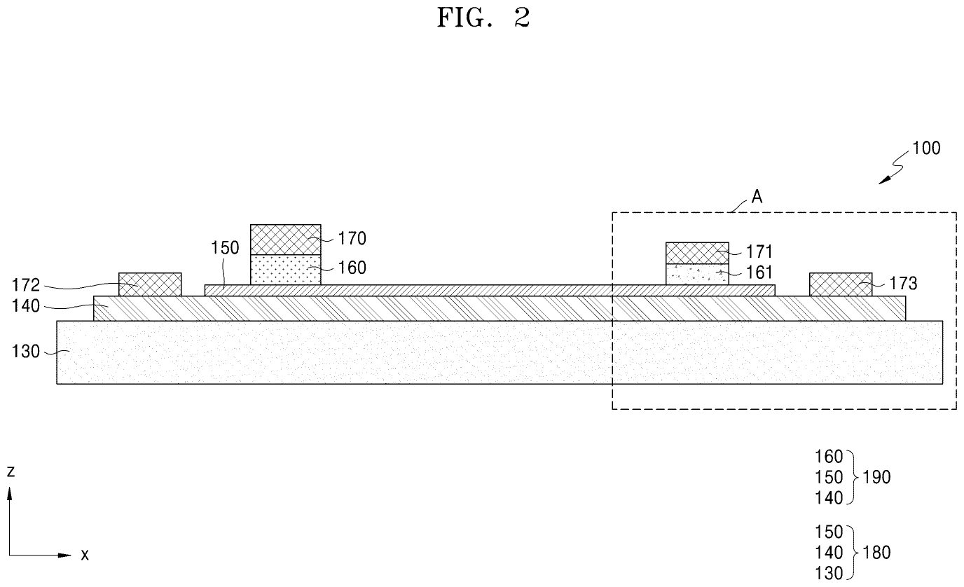

FIG. 1 is a perspective view illustrating a memory device 100 according to some example embodiments. FIG. 2 is a cross-sectional view illustrating a part of the memory device 100 of FIG. 1.

Referring to FIGS. 1 and 2, the memory device 100 may include a substrate 110, a heavy metal layer 130 on the substrate 110, a free layer 140 on the heavy metal layer 130, a dielectric layer 150 on the free layer 140, a pinned layer 160 and a volume change material layer 161 on the dielectric layer 150 and spaced apart from each other.

The memory device 100 may be or may include, for example, a racetrack memory device.

The substrate 110 may include, for example, one or more of Si, Ge, SiGe, or a Group III-V semiconductor material, but is not limited thereto. The substrate 110 may be undoped or may be doped, e.g., lightly doped with an impurity such as but not limited to one or more of boron (B), phosphorus (P), or arsenic (As). A seed layer 120 may be further provided on the substrate 110; example embodiments are not limited thereto.

The heavy metal layer 130 may include non-magnetic heavy metal. The heavy metal layer 130 may include, for example, at least one of iridium (Ir), ruthenium (Ru), tantalum (Ta), platinum (Pt), palladium (Pd), bismuth (Bi), titanium (Ti), tungsten (W), or an alloy thereof, but is not limited thereto.

The free layer 140 may include a ferromagnetic material. The free layer 140 may include, for example, cobalt (Co) or a cobalt (Co) alloy, but is not limited thereto. A magnetic domain may be generated inside the free layer 140.

Magnetic domains may have a uniform magnetization direction, and magnetic domain walls may have magnetization directions varying between magnetic domains in or within the free layer 140. In some example embodiments, adjacent magnetic domains may have magnetic directions that are opposite with, e.g., antiparallel with, each other; example embodiments are not limited hereto. Each of the magnetic domain walls may define a boundary between magnetic domains having different magnetization directions.

The heavy metal layer 130, the free layer 140, and the dielectric layer 150 may be collectively referred to as a racetrack (RT) line 180. A magnetic domain may be moved through the RT-line 180.

The dielectric layer 150 may include a metal oxide. The dielectric layer 150 may include an oxide including magnesium (Mg). For example, the dielectric layer 150 may include MgO and/or AIOx, and in some example embodiments may be doped or undoped. The dielectric layer 150 may be configured as a double layer.

The pinned layer 160 may have a pinned magnetization direction. Once determined, the magnetization direction of the pinned layer 160 may not be changed. In some example embodiments, the free layer 140 may have a variable magnetization direction. Data may be read corresponding to the magnetization direction of the free layer 140.

The free layer 140, the dielectric layer 150, and the pinned layer 160 may form a magnetic tunnel junction (MTJ) structure. In this regard, the dielectric layer 150 may serve as a tunnel barrier for MTJ. The free layer 140, the dielectric layer 150, and the pinned layer 160 may be referred to as a tunneling magnetoresistance layer 190. Data may be read through the tunneling magnetoresistance layer 190. Data may be read through tunnel magnetoresistance (TMR) values of the tunneling magnetoresistance layer 190.

The volume change material layer 161 may include a ferroelectric material. The volume change material layer 161 may include, for example, one or more of HfO₂, Hf₁₋ₓZrₓO₂(1<x<0), Hf₁₋ₓAlₓO₂(1<x<0), BaTiO₃, or PbZr₁₋ₓTₓO₃(1<x<0). The volume change material layer 161 may include a piezoelectric material. The volume change material layer 161 may include a nitride and/or an oxide. The volume change material layer 161 may include, for example, one or more of GaN, InN, AlN, BaTiO₃, PbZr₁₋ₓTiₓO₃(1<x<0), BiFeO₃, or ZnO. The volume change material layer 161 may remain in a polarization state at an applied voltage even after removing the applied voltage.

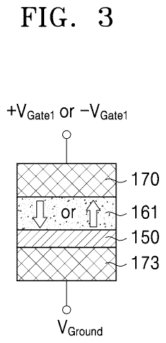

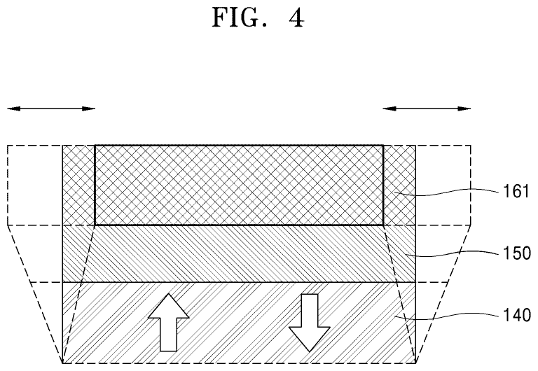

A magnetic domain may be generated in the RT-line 180 through an inverse magnetostrictive effect by a current applied to the volume change material layer 161. This will be described in detail below with reference to FIGS. 3 and 4.

A first electrode 170 may be on the pinned layer 160. The first electrode 170 may include, for example, TiN and/or Au. A second electrode 171 may be on the volume change material layer 161. The second electrode 171 may include, for example, TiN. A third electrode 172 and a fourth electrode 173 may be on the free layer 140. The third electrode 172 may include, for example, TiN and/or Au. The fourth electrode 173 may include, for example, TiN and/or Au.

The memory device 100 according to some example embodiments may include the volume change material layer 161, thereby injecting the magnetic domain through the inverse magnetostrictive effect, and/or improving stability of the injected magnetic domain.

In some example embodiments, the pinned layer 160 and/or the first electrode 170 may have a circular and/or rounded shape when viewed in plan view. Example embodiments are not limited thereto. Alternatively or additionally in some example embodiments, the volume change material 161 and/or the second electrode 171 may have a rectangular shape, e.g., a square shape when viewed in plan view. Example embodiments are not limited thereto.

FIG. 3 is a diagram illustrating a device corresponding to a part A of FIG. 2.

Referring to FIG. 3, the heavy metal layer 130 and the free layer 140 of FIG. 2 operate as electrodes, and accordingly, the device of FIG. 3 may correspond to the part A of FIG. 2.

For example, when +V_{Gate1} is applied to the first electrode 170 and the fourth electrode 173 is grounded, an internal polarization direction of the volume change material layer 161 may be directed downward. When −V_{Gate1} is applied to the first electrode 170, and the fourth electrode 173 is grounded, the internal polarization direction of the volume change material layer 161 may be directed upward. Meanwhile, the third electrode 172 may be grounded instead of the fourth electrode 1173. A direction of a magnetic domain may be determined through a voltage applied to the first electrode 170.

Meanwhile, an arrow direction of FIG. 3 is one of examples of available directions. The arrow direction shown in FIG. 3 is for illustration only and is not limited thereto. FIG. 4 is a diagram illustrating a part of a device for describing an inverse magnetostrictive effect.

Referring to FIG. 4, a magnetic domain may be generated in the free layer 140 through the inverse magnetostrictive effect by a current applied to the volume change material layer 161.

In some example embodiments, the volume change material layer 161 includes a material exhibiting piezoelectric characteristics, and thus, when the current is applied to the volume change material layer 161, a volume change occurs. According to the volume change of the volume change material layer 161, the volume of the dielectric layer 150 below the volume change material layer 161 changes, and accordingly, the volume of the free layer 140 below the dielectric layer 150 changes. The volume change of the free layer 140 changes a lattice constant of a ferromagnetic material of the free layer 140, which changes a magnetic moment of the ferromagnetic material.

In some example embodiments, the magnetic domain may be generated in the free layer 140 by the current applied to the volume change material layer 161.

Meanwhile, an arrow direction of FIG. 4 is one of examples of available directions. The arrow direction shown in FIG. 4 is for illustration only and is not limited thereto.

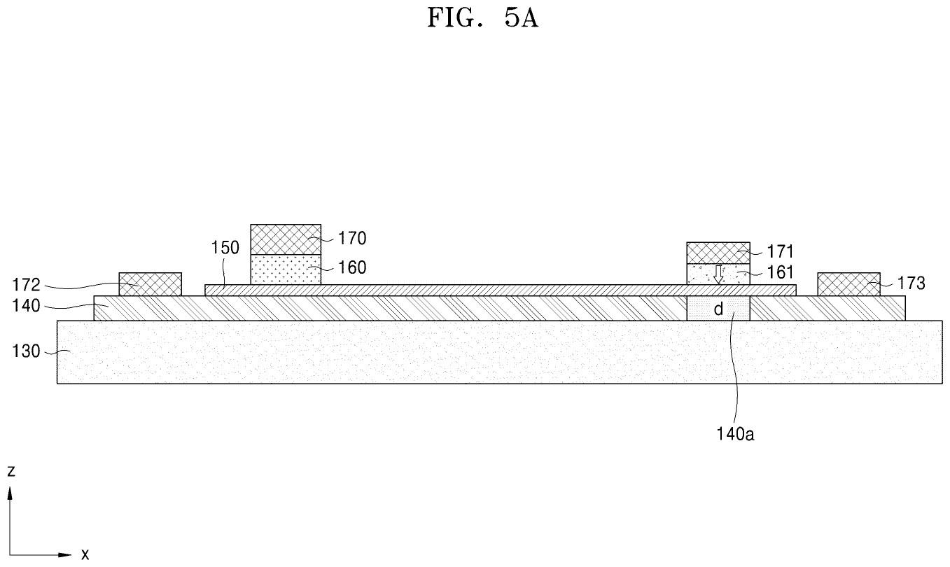

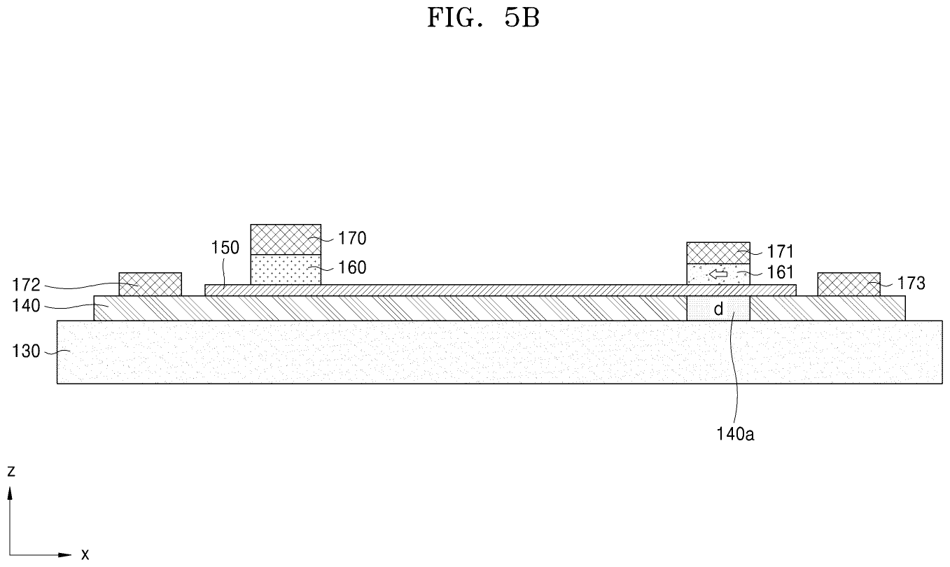

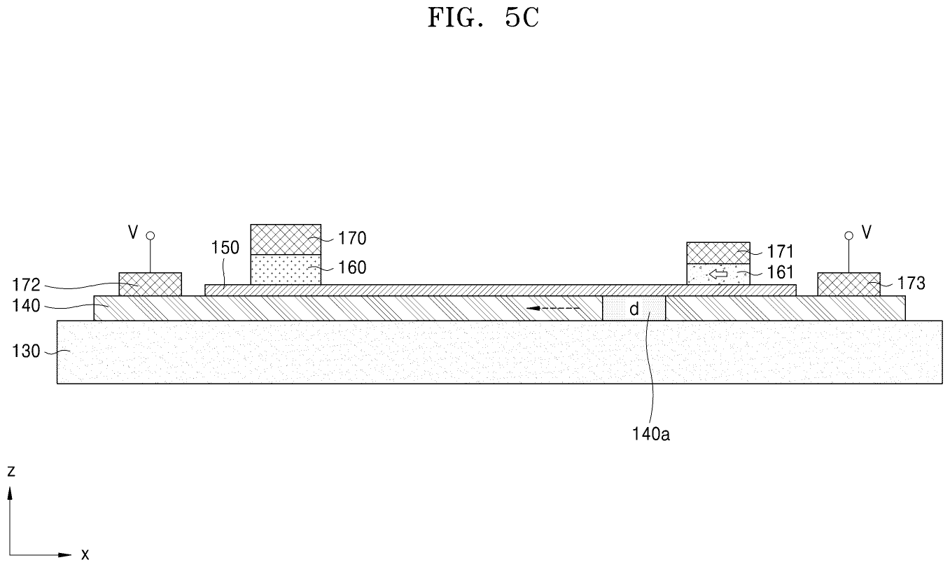

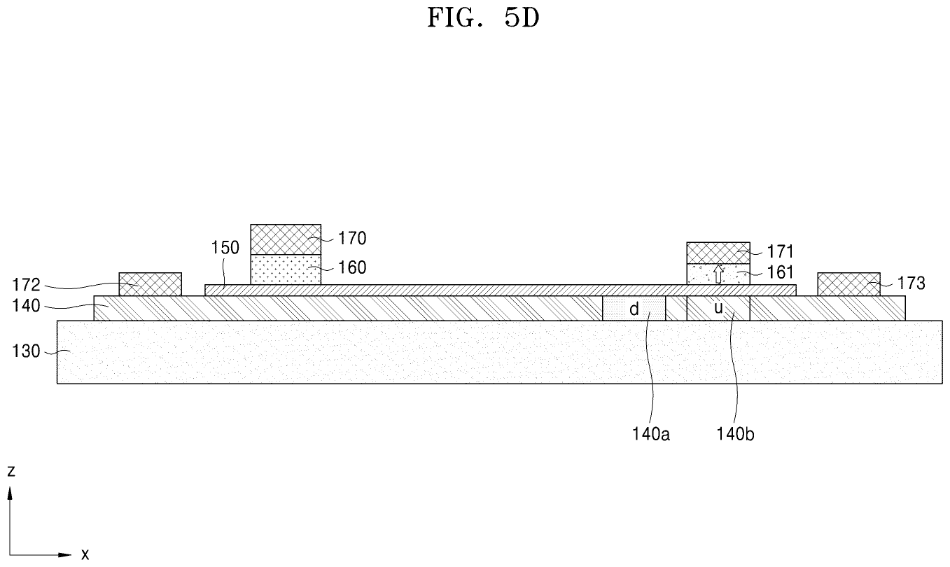

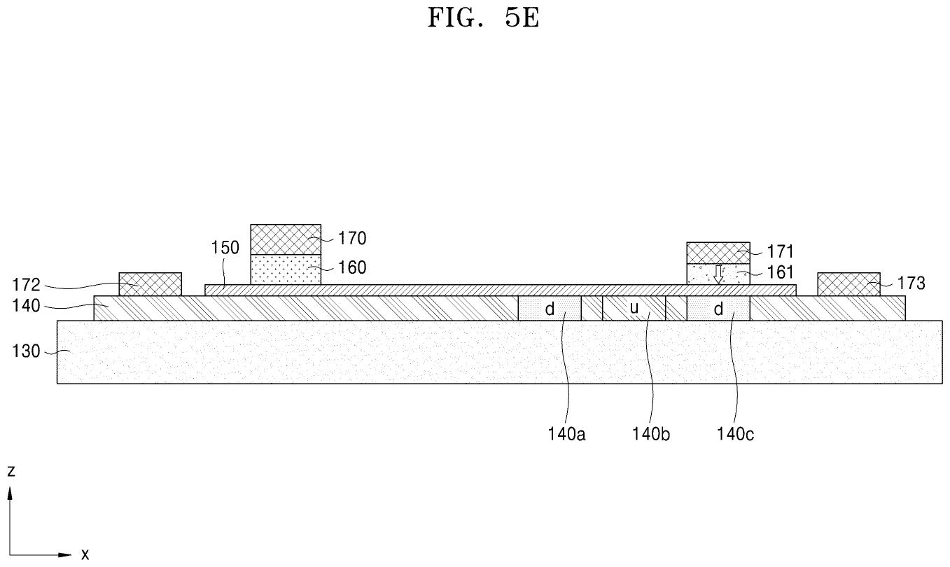

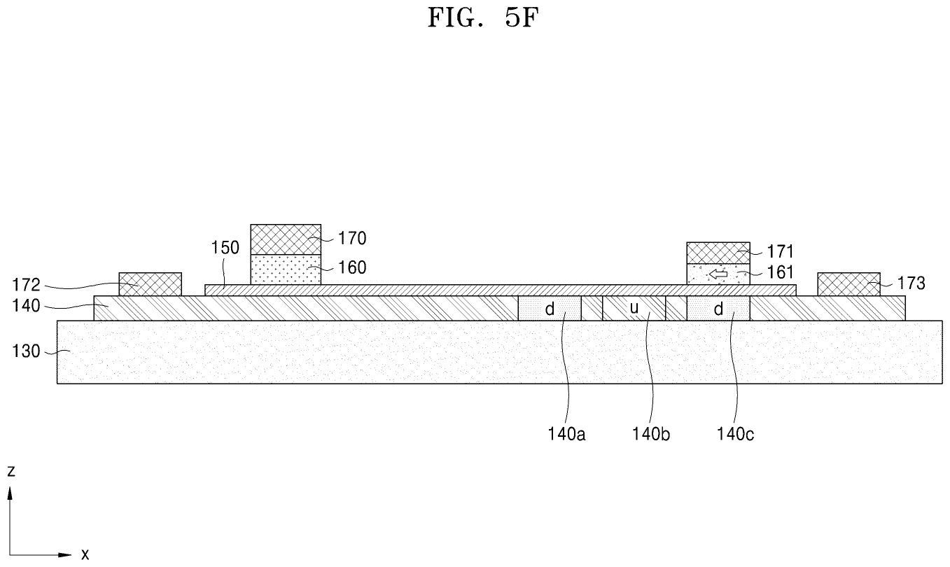

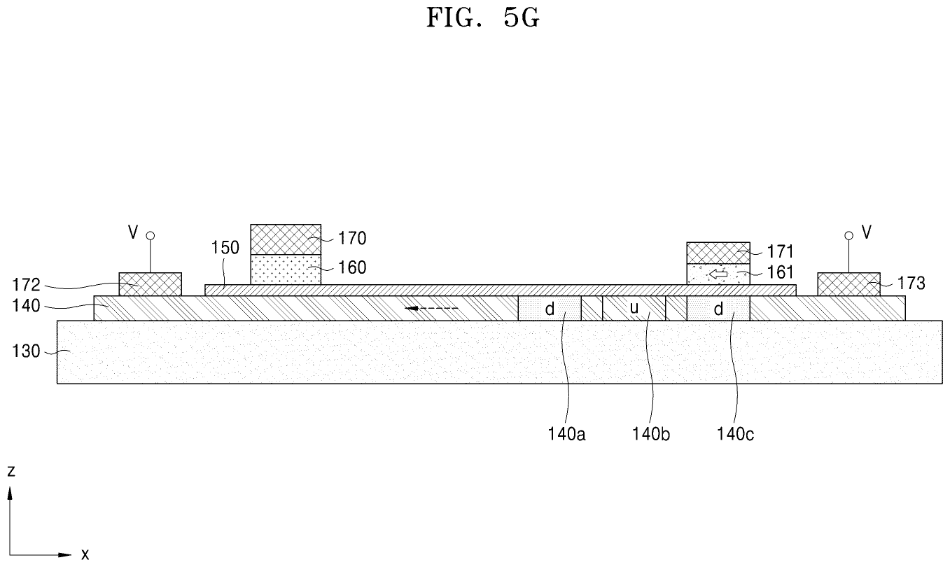

FIGS. 5A to 5G are diagrams illustrating a data writing method of a memory device according to some example embodiments.

Referring to FIG. 5A, the volume change material layer 161 may generate a magnetic domain in the free layer 140 based on an applied current.

When the voltage is applied to the volume change material layer 161 through the second electrode 171, a magnetic domain of which magnetization direction is a perpendicular direction (e.g., +Z direction) or a magnetic domain of which magnetization direction is a direction (e.g., −Z direction) opposite to the perpendicular direction may be generated in the free layer 140. The magnetic domain of which magnetization direction is the perpendicular direction may be referred to as an up domain u, and the magnetic domain of which magnetization direction is the direction opposite to the perpendicular direction may be referred to as a down domain d.

In FIG. 5A, a first magnetic domain 140a having a down domain d of which magnetization direction is the direction opposite to the perpendicular direction by applying, for example, a voltage of −10 V to the volume change material layer 161 through the second electrode 171. At this stage, a magnetic domain wall may be formed.

Referring to FIG. 5B, the first magnetic domain 140a may be determined by reducing an absolute value of the voltage applied to the volume change material layer 161 through the second electrode 171 to, for example, −5 V.

Referring to FIG. 5C, the first magnetic domain 140a may be moved to or during a read operation. The first magnetic domain 140a may be moved by opening one of the third electrode 172 and the fourth electrode 173, and applying a high voltage to the other of the third electrode 172 and the fourth electrode 173.

Referring to FIG. 5D, the volume change material layer 161 may generate a new magnetic domain in the free layer 140 based on the applied current. For example, a second magnetic domain 140b of which magnetization direction is the perpendicular direction having an up domain u may be formed by applying a voltage of 10 V to the volume change material layer 161 through the second electrode 171. The second magnetic domain 140b may be determined by reducing the absolute value of the voltage applied to the volume change material layer 161 through the second electrode 171 to, for example, 5 V, and the first magnetic domain 140a and the second magnetic domain 140b may be moved by opening one of the third electrode 172 and the fourth electrode 173, and applying a high voltage to the other of the third electrode 172 and the fourth electrode 173.

Referring to FIG. 5E, a third magnetic domain 140c of which magnetization direction is the direction opposite to the perpendicular direction and having a down domain d may be formed by applying, for example, a voltage of −10 V to the volume change material layer 161 through the second electrode 171.

Referring to FIG. 5F, the third magnetic domain 140c may be determined by reducing an absolute value of the voltage applied to the volume change material layer 161 through the second electrode 171 to, for example, −5 V.

Referring to FIG. 5G, the first magnetic domain 140a, the second magnetic domain 140b, and the third magnetic domain 140c may be moved during a read operation. The first magnetic domain 140a, the second magnetic domain 140b, and the third magnetic domain 140c may be moved by opening one of the third electrode 172 and the fourth electrode 173, and applying a high voltage to the other of the third electrode 172 and the fourth electrode 173.

Meanwhile, an arrow direction of each of FIGS. 5A to 5G is one of examples of available directions. The arrow directions shown in FIGS. 5A to 5G are only for illustrating the disclosure and are not limited thereto.

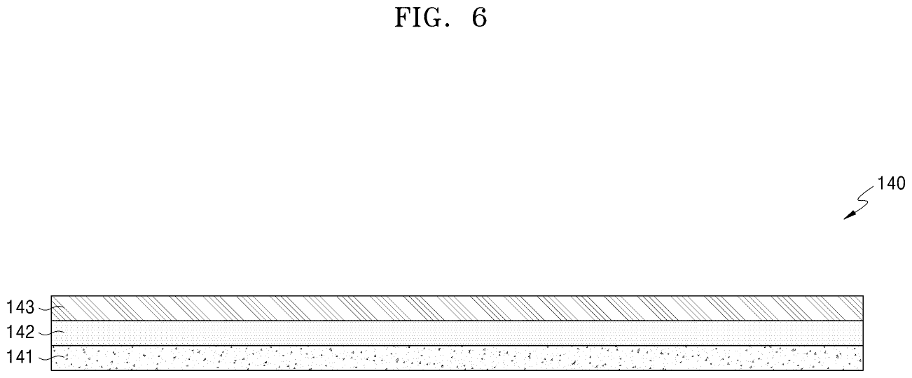

FIG. 6 is a diagram illustrating the free layer 140 of a memory device according to some example embodiments.

Referring to FIG. 6, the free layer 140 may have a synthetic anti-ferromagnetic (SAF) structure.

The free layer 140 may include a first ferromagnetic layer 141, a non-magnetic layer 142, and a second ferromagnetic layer 143. The first ferromagnetic layer 141 may include, for example, CoNiCo. The non-magnetic layer 142 may include, for example, one or more of platinum (Pt), tungsten (W), tantalum (Ta), ruthenium (Ru), chromium (Cr), rhodium (Rh), palladium (Pd), molybdenum (Mo), niobium (Nb), or nickel (Ni). The second ferromagnetic layer 143 may include, for example, CoFeB.

When the free layer 140 of FIG. 6 is provided at a position of the free layer 140 of FIG. 1, the dielectric layer 150 including MgO is on the second ferromagnetic layer 143, so that the second ferromagnetic layer 143 has a perpendicular magnetic anisotropy (PMA) characteristic.

In addition, as described with reference to FIG. 4, when a current is applied to the volume change material layer 161, the volume of the dielectric layer 150 below the volume change material layer 161 changes according to the volume change of the volume change material layer 161, and accordingly, the volume of the free layer 140 below the dielectric layer 150 changes. The volume change of the free layer 140 changes a lattice constant of a ferromagnetic material of the free layer 140, and accordingly, magnetic moments of the first ferromagnetic layer 141 and the second ferromagnetic layer 143 may be changed.

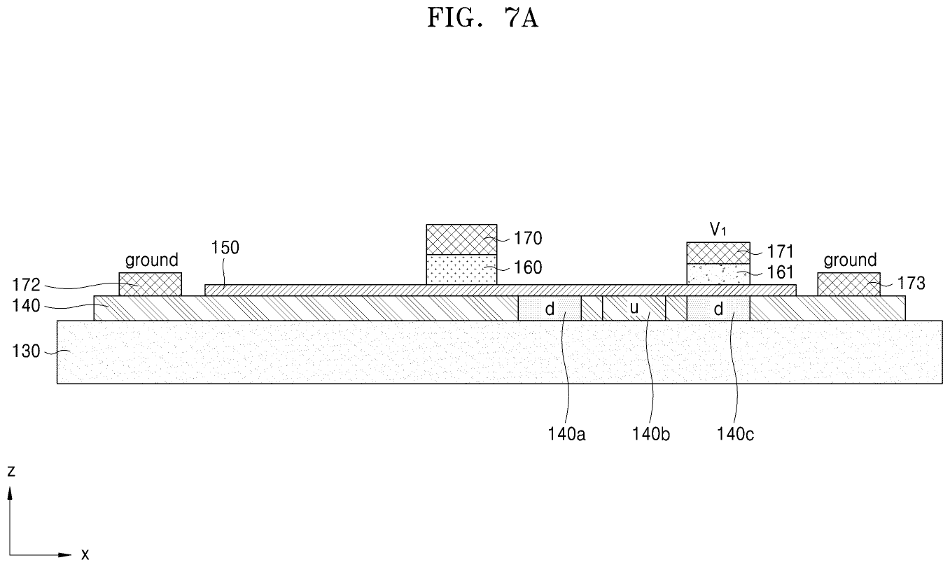

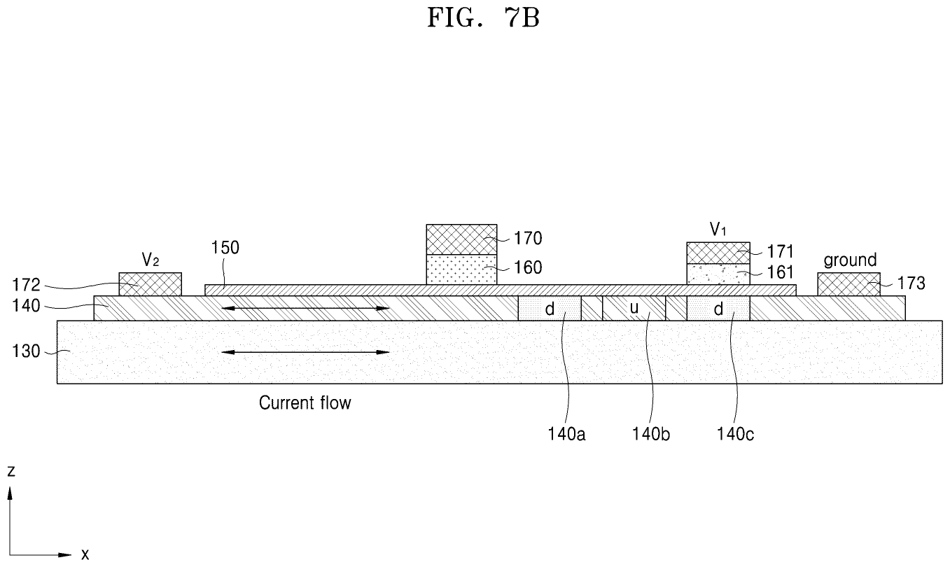

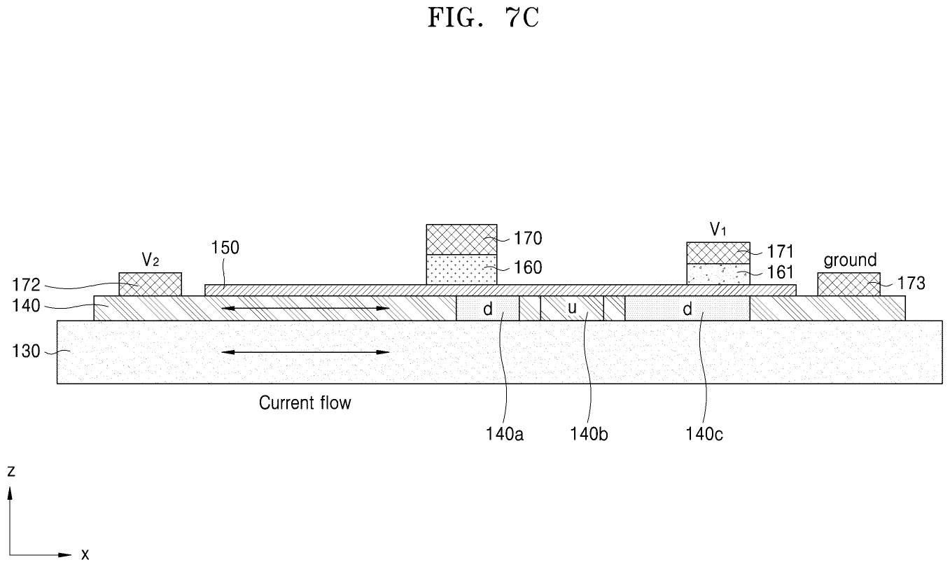

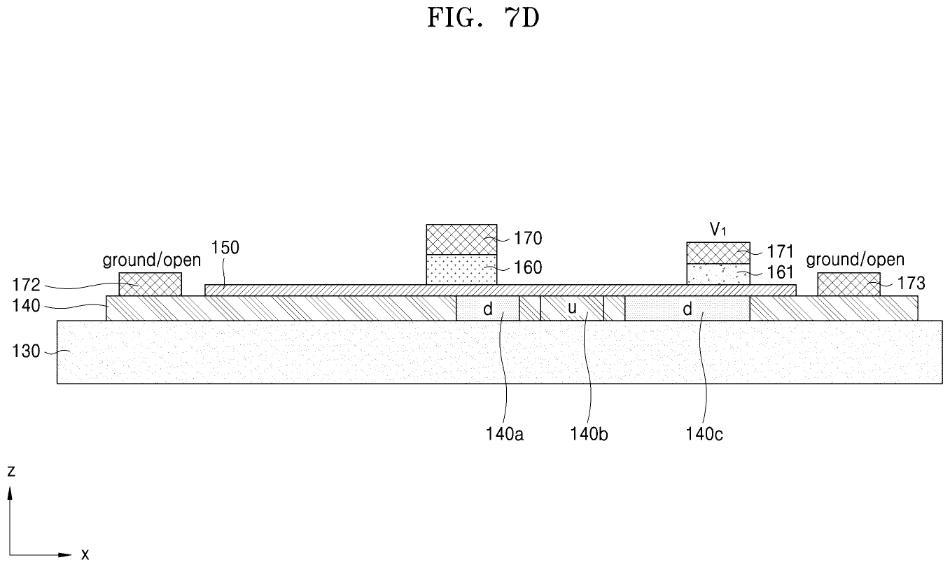

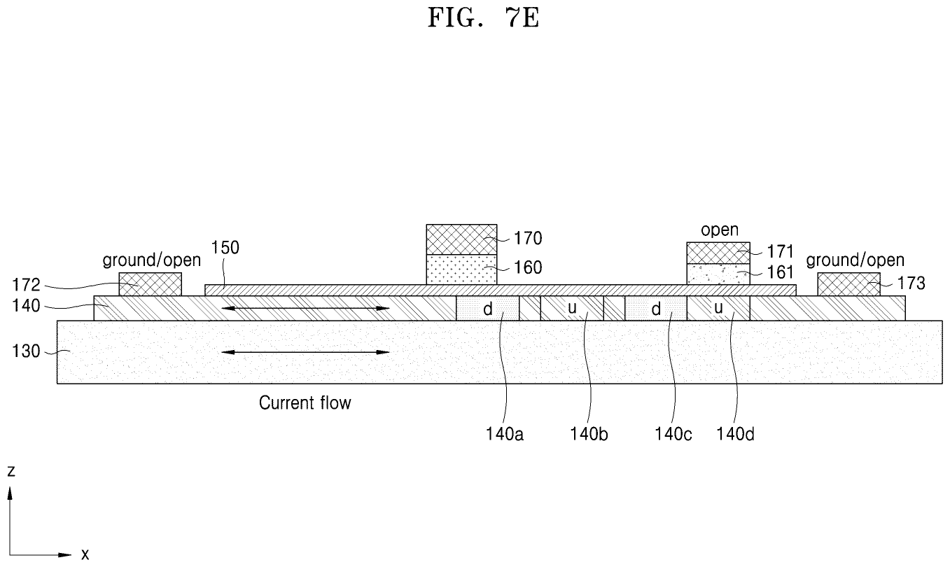

FIGS. 7A to 7E are diagrams illustrating a data writing method of a memory device according to some example embodiments.

In the memory device according to the embodiment of FIGS. 7A to 7E, a piezoelectric material is used for the volume change material layer 161. The data writing method of the memory device according to the embodiment of FIGS. 7A to 7E relates to a single bit data writing method.

Referring to FIG. 7A, the volume change material layer 161 may generate a magnetic domain in the free layer 140 based on an applied current. The third magnetic domain 140c of which magnetization direction is a direction opposite to a perpendicular direction and having a down domain d may be formed by applying V₁ to the volume change material layer 161 through the second electrode 171. V₁ is maintained below a threshold voltage allowing a current to flow from the third electrode 172 or the fourth electrode 173 to the second electrode 171. The piezoelectric material of the volume change material layer 161 continues to maintain a volume change condition.

Referring to FIG. 7B, V₂ is applied to the third electrode 172 and the fourth electrode 173 is grounded. A current flows between the third electrode 172 and the fourth electrode 173.

Referring to FIG. 7C, the third magnetic domain 140c is moved by the current flowing between the third electrode 172 and the fourth electrode 173.

Referring to FIG. 7D, the third electrode 172 is grounded or opened (e.g., to a floating state), and the fourth electrode 173 is grounded or opened (e.g., to a floating state). Movement of the third magnetic domain 140c is stopped.

Referring to FIG. 7E, the second electrode 171 is opened. The piezoelectric material of the volume change material layer 161 that continues to maintain the volume change condition is changed to the existing volume condition. The free layer 150 below the piezoelectric material is also changed to the existing volume condition. A fourth magnetic domain 140d of which magnetization direction is the perpendicular direction is formed below the free layer 150.

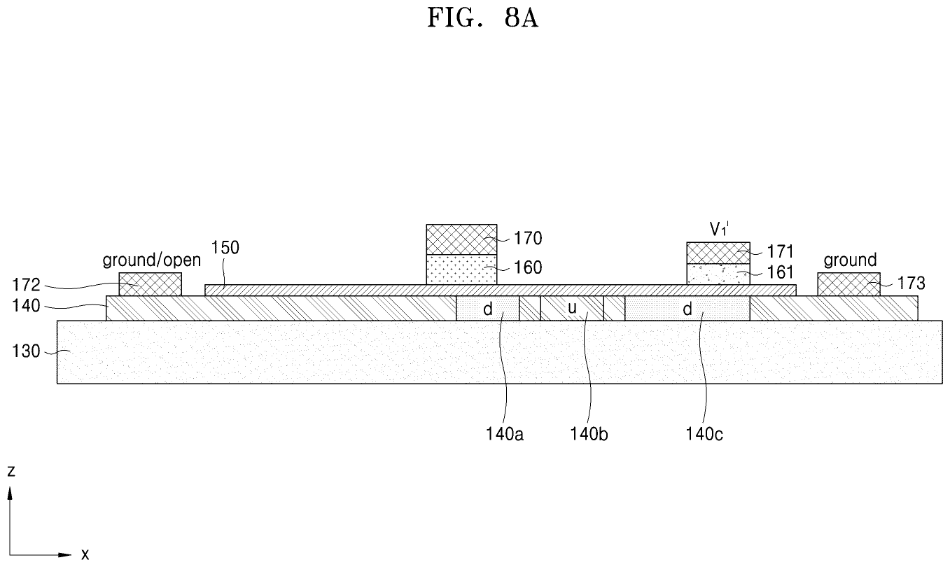

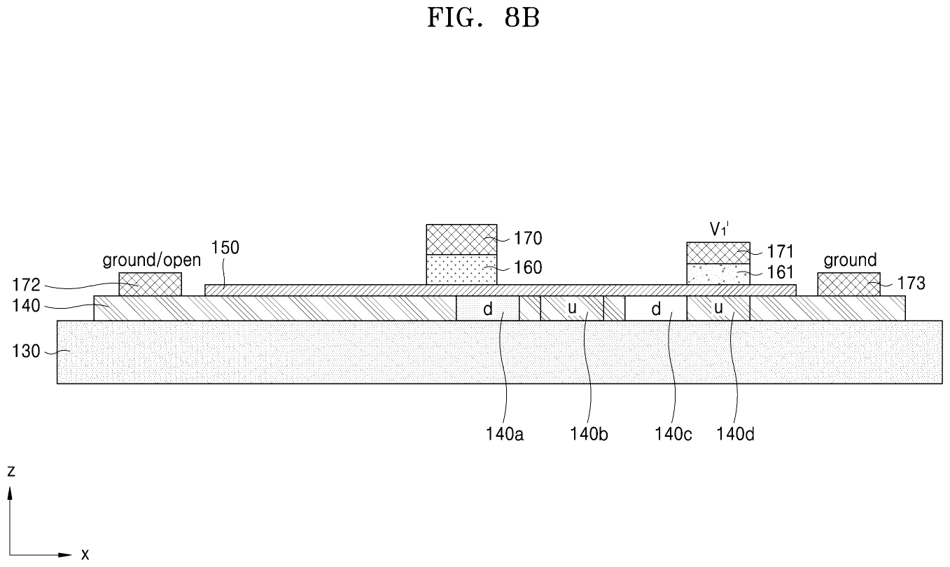

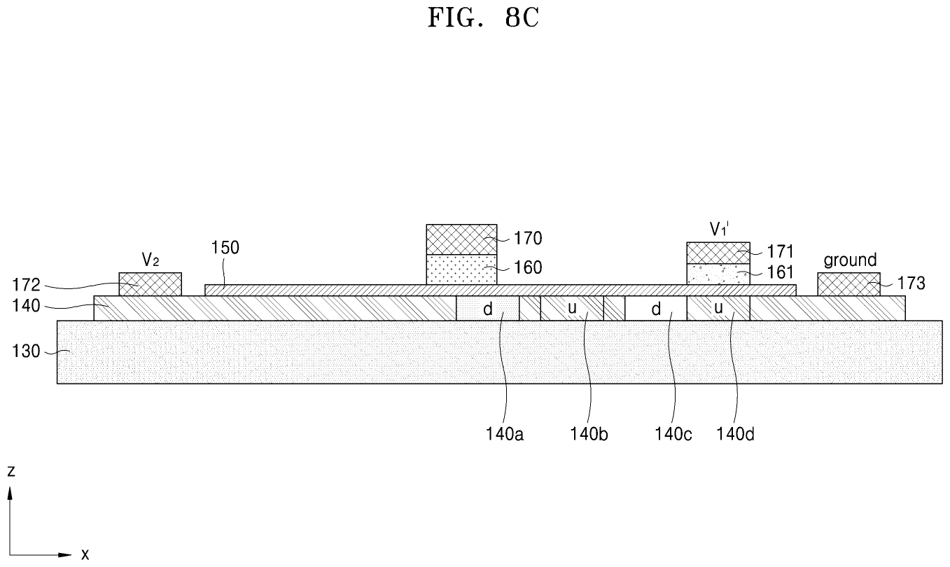

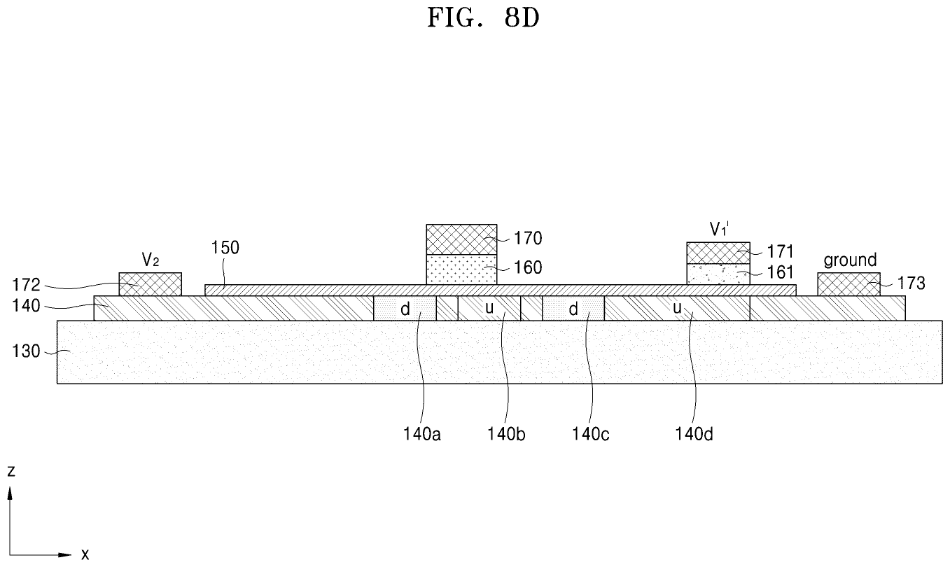

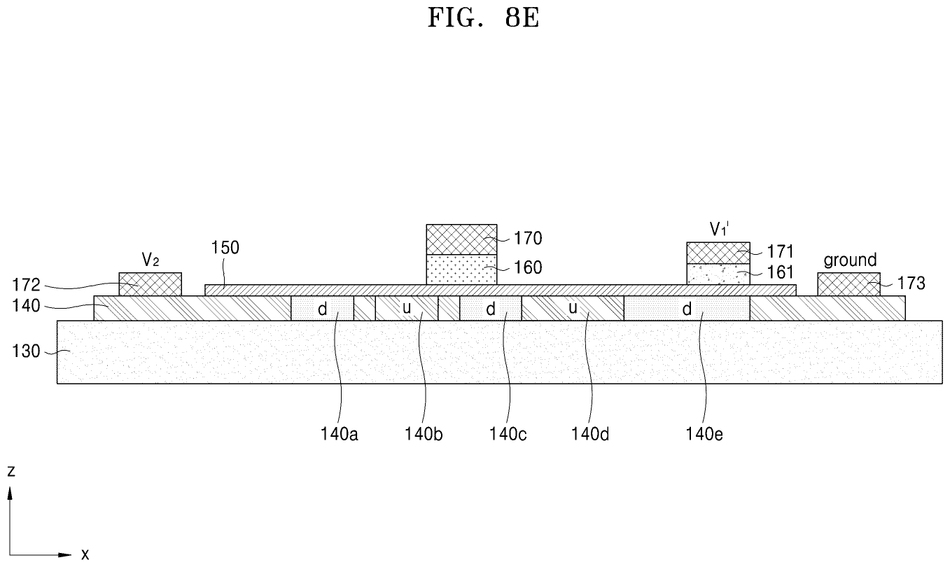

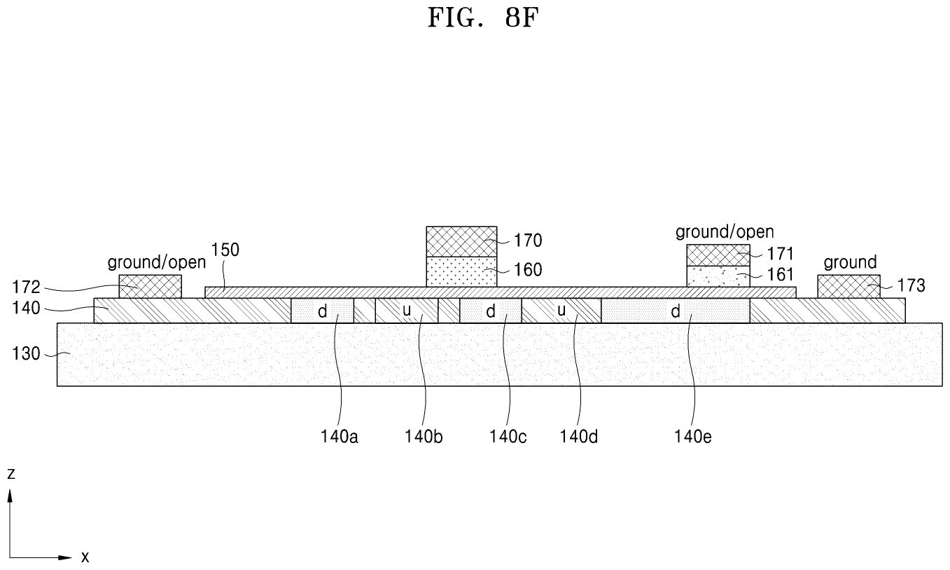

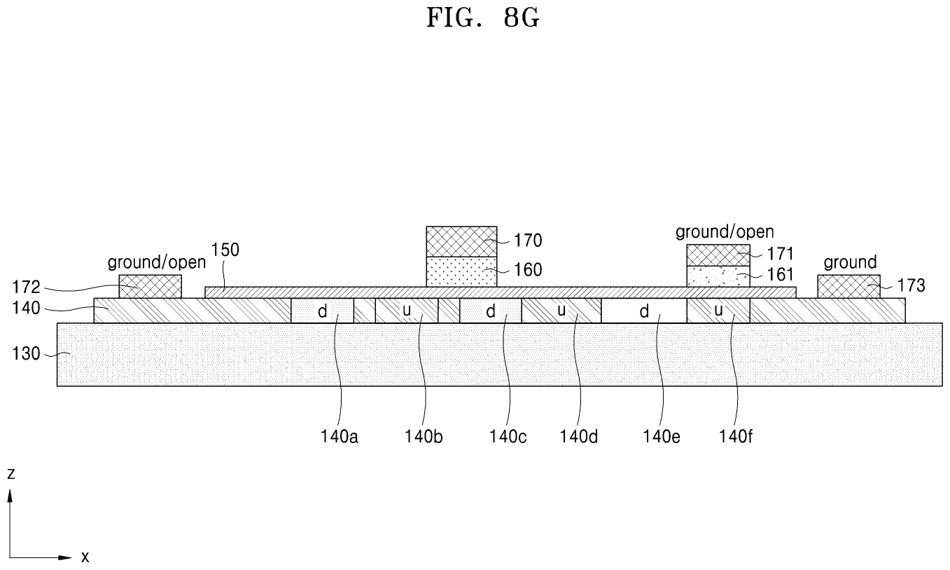

FIGS. 8A to 8G are diagrams illustrating a data writing method of a memory device according to some example embodiments.

In the memory device according to the embodiment of FIGS. 8A to 8G, a piezoelectric material is used for the volume change material layer 161. The data writing method of the memory device according to the embodiment of FIGS. 8A to 8G relates to a multi bit data writing method. Operations of FIGS. 7A to 7D may be performed before operations of FIGS. 8A to 8G.

Referring to FIG. 8A, V₁′ is applied to the second electrode 171. V₁′ is or corresponds to a voltage that induces a magnetic domain having a magnetization direction opposite to a magnetization direction of the third magnetic domain 140c.

Referring to FIG. 8B, the fourth magnetic domain 140d having a magnetization direction opposite to the magnetization direction of the third magnetic domain 140c may be formed by V₁′ applied to the second electrode 171.

Referring to FIG. 8C, V₂ is applied to the third electrode 172. A current flows between the third electrode 172 and the fourth electrode 173.

Referring to FIG. 8D, the fourth magnetic domain 140d is moved by the current flowing between the third electrode 172 and the fourth electrode 173.

Referring to FIG. 8E, the operations of FIGS. 8A to 8D are repeated until a data writing process is completed. Accordingly, a fifth magnetic domain 140e may be formed. During this process, V₁′ applied to the second electrode 171 and V₂ applied to the third electrode 172 may be appropriately controlled to prevent an electrical short-circuit.

Referring to FIG. 8F, the second electrode 171 and the third electrode 172 are opened. Movement of the fifth magnetic domain 140e is stopped.

Referring to FIG. 8G, the piezoelectric material of the volume change material layer 161 is changed to the existing volume condition. The free layer 150 below the piezoelectric material is also changed to the existing volume condition. The fifth magnetic domain 140e of which magnetization direction is the perpendicular direction is formed below the free layer 150. Through the process, multi-bit data writing is possible.

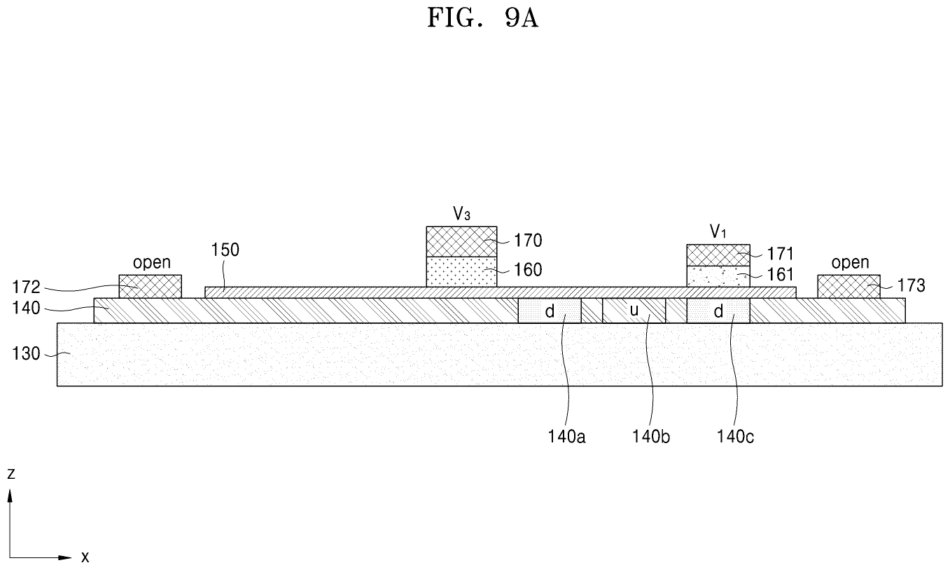

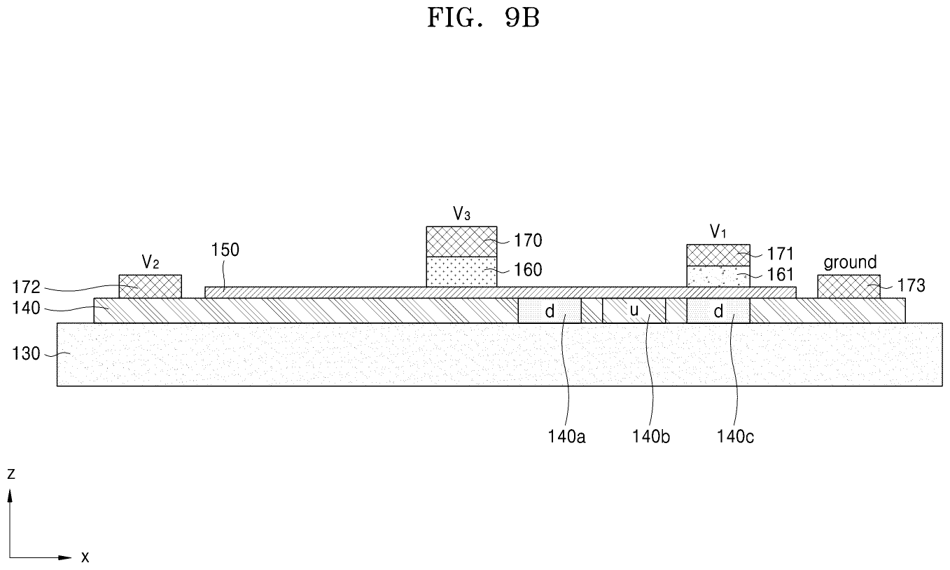

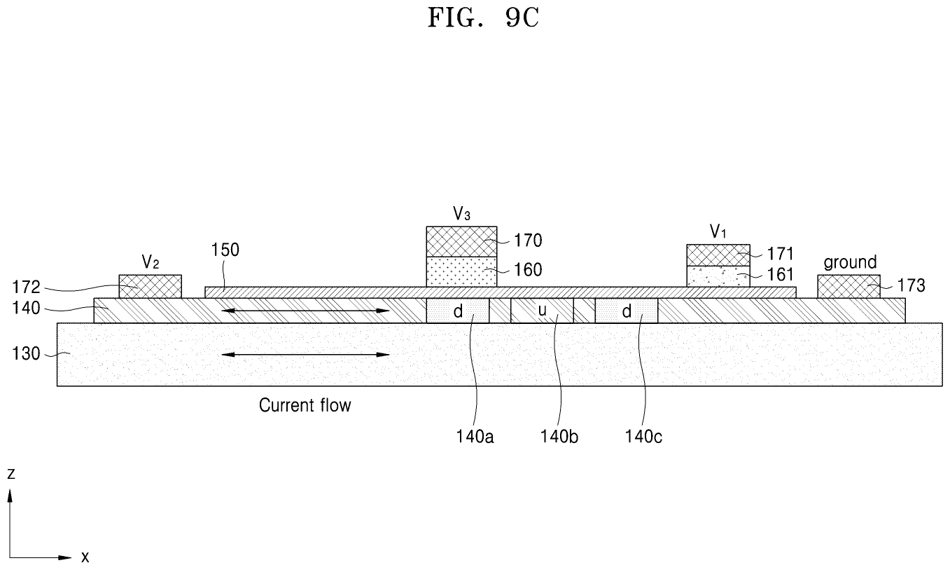

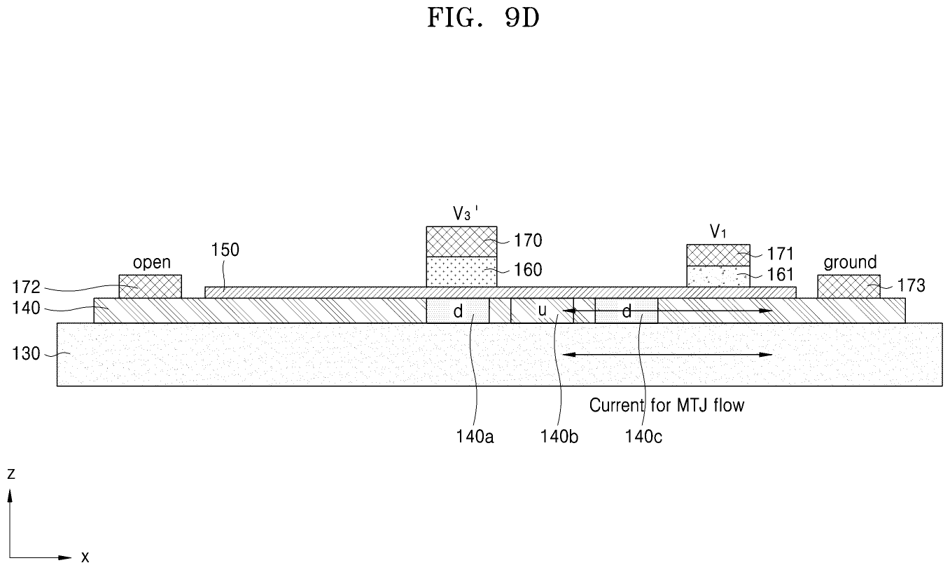

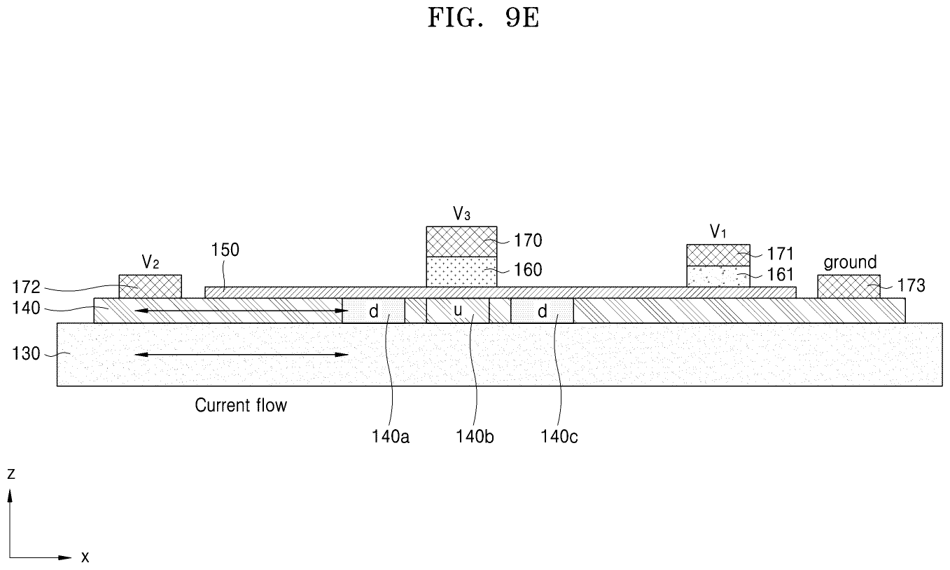

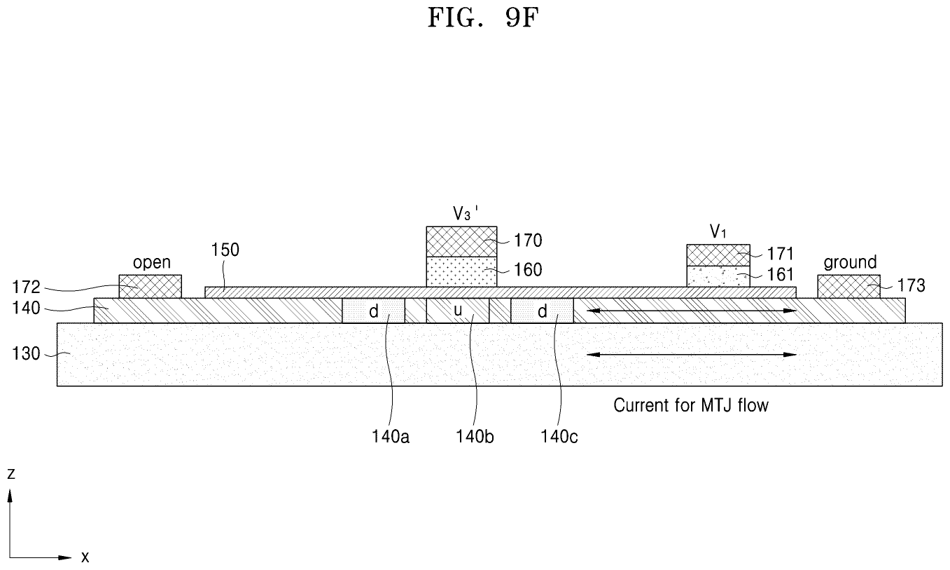

FIGS. 9A to 9F are diagrams illustrating a data reading method of a memory device according to some example embodiments. In the memory device according to the embodiment of FIGS. 9A to 9F, a piezoelectric material is used for the volume change material layer 161.

Referring to FIG. 9A, V₃ is applied to the first electrode 170 and V₁ is applied to the second electrode 171. The third electrode 172 and the fourth electrode 173 are opened. V₃ is not a voltage for reading data.

Referring to FIG. 9B, V₂ is applied to the third electrode 172, and the fourth electrode 173 is grounded. A current flows between the third electrode 172 and the fourth electrode 173.

Referring to FIG. 9c, the first magnetic domain 140a, the second magnetic domain 140b, and the third magnetic domain 140c are moved by the current flowing between the third electrode 172 and the fourth electrode 173. The first magnetic domain 140a may be moved to a position at which the first magnetic domain 140a overlaps the pinned layer 160 in a perpendicular direction (e.g., Z direction).

Referring to FIG. 9D, V₃′ is applied to the first electrode 170, and the third electrode 172 is opened. V₃′ is a voltage for reading data. The first magnetic domain 140a overlapping the pinned layer 160 in the perpendicular direction (e.g., Z direction) may be read by applying V₃′ to the third electrode 172.

Referring to FIGS. 9E and 9F, the second magnetic domain 140b may be moved to a position overlapping the pinned layer 160 in the perpendicular direction (e.g., Z direction) and read. The third magnetic domain 140c may be also read by repeating operations of FIGS. 9C and 9D.

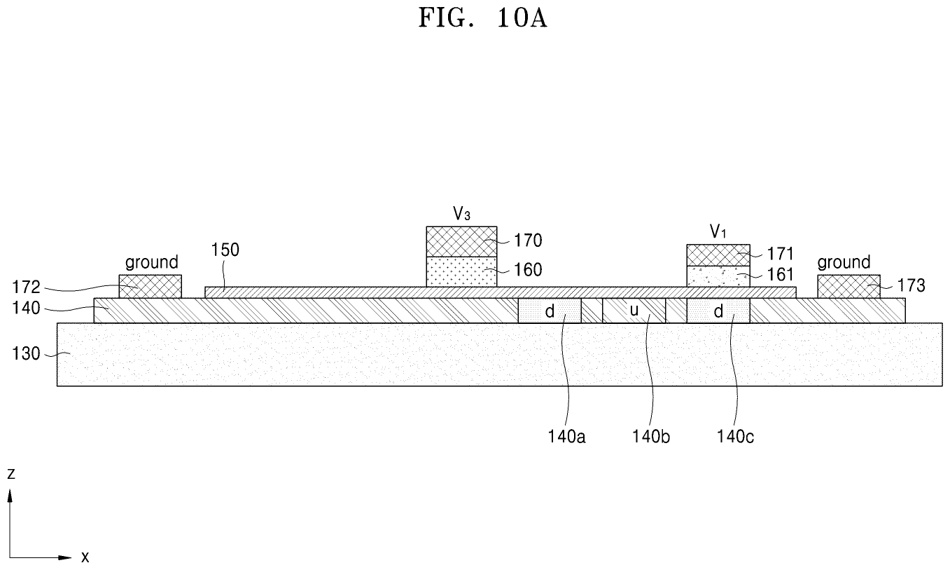

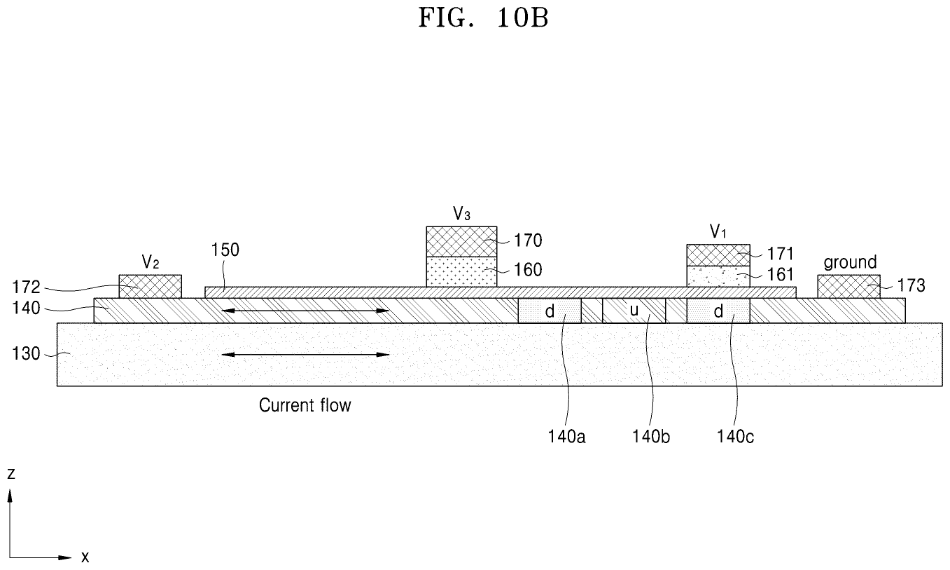

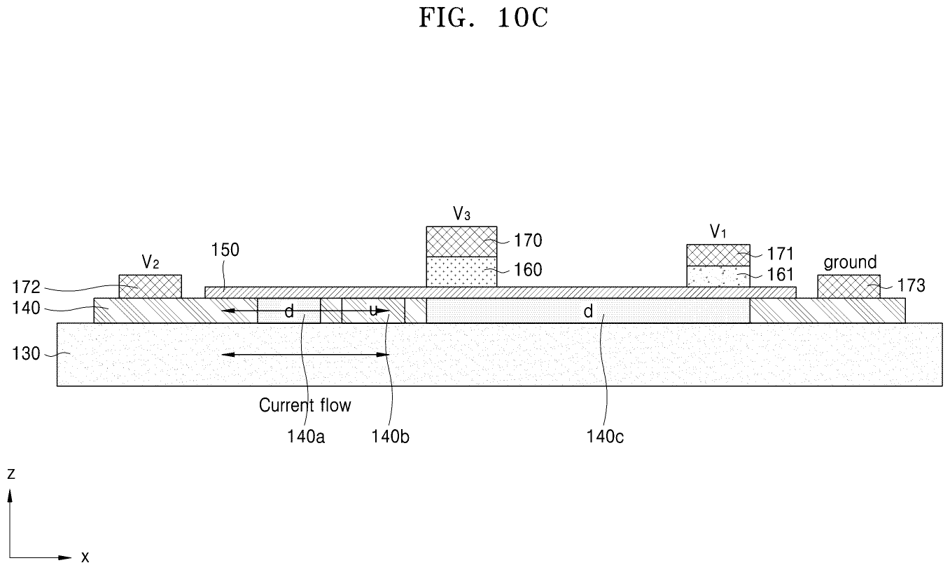

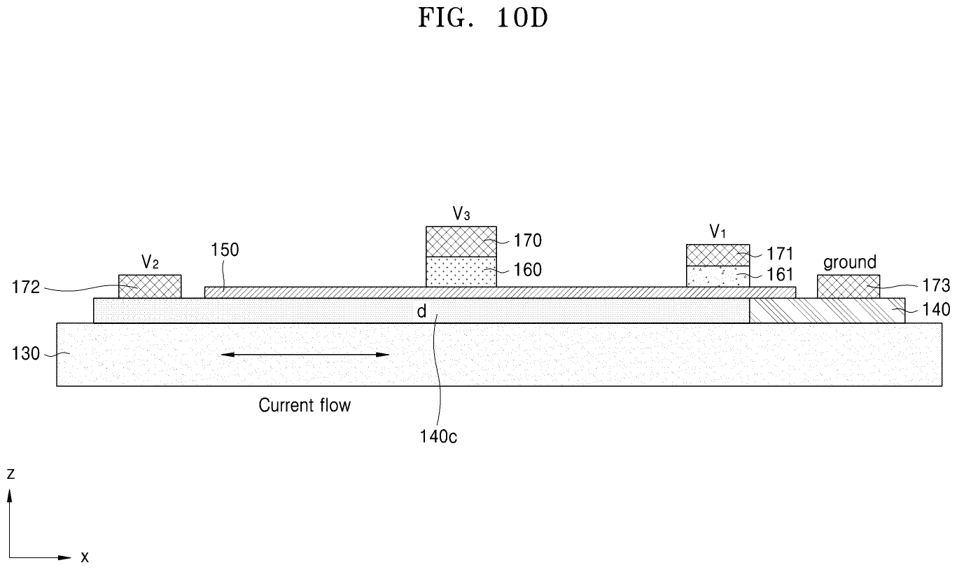

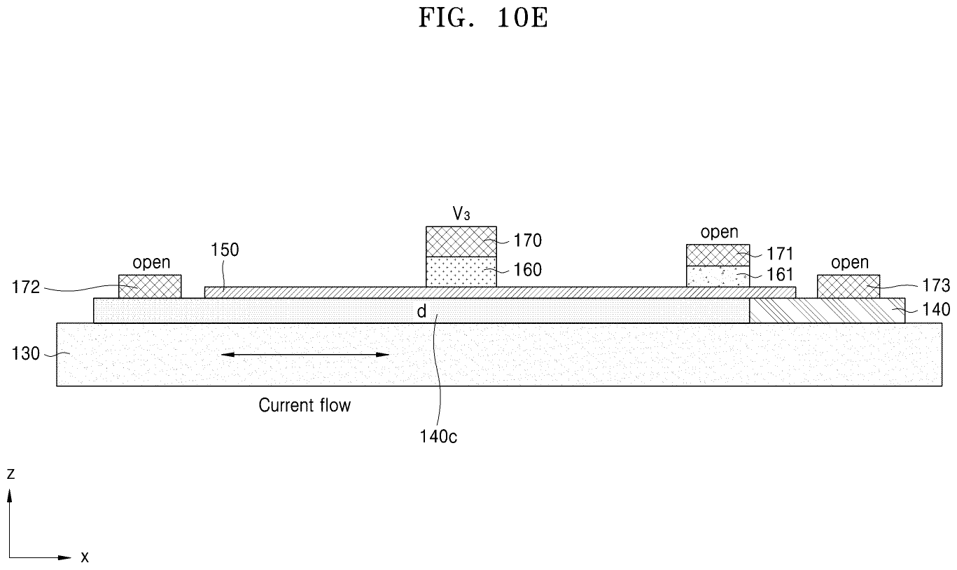

FIGS. 10A to 10E are diagrams for describing a RT-line initializing method of a memory device according to some example embodiments. In the memory device according to the embodiment of FIGS. 10A to 10E, a piezoelectric material is used for the volume change material layer 161.

Referring to FIG. 10A, V₃ is applied to the first electrode 170, and V₁ is applied to the second electrode 171. The third electrode 172 and the fourth electrode 173 are grounded. V₁ is maintained below a threshold voltage allowing a current to flow from the third electrode 172 or the fourth electrode 173 to the second electrode 171. The piezoelectric material of the volume change material layer 161 continues to maintain a volume change condition.

Referring to FIG. 10B, V₂ is applied to the third electrode 172 and the fourth electrode 173 is grounded. A current flows between the third electrode 172 and the fourth electrode 173.

Referring to FIGS. 10C and 10D, the third magnetic domain 140c is moved by the current flowing between the third electrode 172 and the fourth electrode 173. While current flows, magnetic domains below the volume change material layer 161 have the same magnetic moment direction. During this process, V₁ applied to the second electrode 171 and V₂ applied to the third electrode 172 may be appropriately controlled to prevent or reduce the likelihood of and/or impact from an electrical short-circuit.

Referring to FIG. 10E, the second electrode 171, the third electrode 172, and the fourth electrode 173 are opened. Movement of the third magnetic domain 140c is stopped. Through the process, the RT-line of the memory device may be initialized.

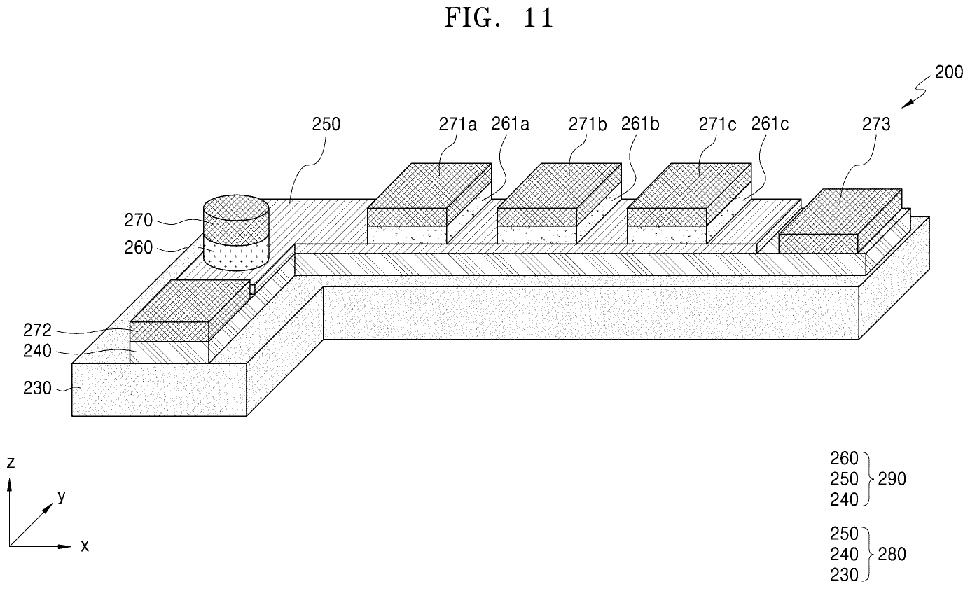

FIG. 11 is a perspective view illustrating a memory device 200 according to some example embodiments.

Referring to FIG. 11, the memory device 200 may include a heavy metal layer 230, a free layer 240 on the heavy metal layer 230, a dielectric layer 250 on the free layer 240, a pinned layer 260 spaced apart from the dielectric layer 250, and a plurality of volume change material layers 261a, 261b, and 261c. The memory device 200 may be, for example, a racetrack memory device. The memory device 200 may have, for example, an ‘L’ shape.

A first electrode 270 may be on the pinned layer 260. The first electrode 270 may include, for example, TiN or Au. A second electrode 271a, a third electrode 271b, and a fourth electrode 271c may be on the plurality of volume change material layers 261a, 261b, and 261c, respectively. The second electrode 271a, the third electrode 271b, and the fourth electrode 271c may each include, for example, TiN.

A fifth electrode 272 and a sixth electrode 273 may be on the free layer 240. The fifth electrode 272 may include, for example, TiN or Au, and the sixth electrode 273 may include, for example, TiN or Au.

The memory device 200 may include the plurality of volume change material layers 261a, 261b, and 261c, thereby generating a plurality of magnetic domains in the free layer 240 based on the applied current. To generate the plurality of magnetic domains, voltages need to be sequentially applied to the second electrode 271a, the third electrode 271b, and the fourth electrode 271c.

The memory device 200 according to some example embodiments may be the same as the memory device 100 of FIG. 1 except that the memory device 200 may include the plurality of volume change material layers 261a, 261b, and 261c.

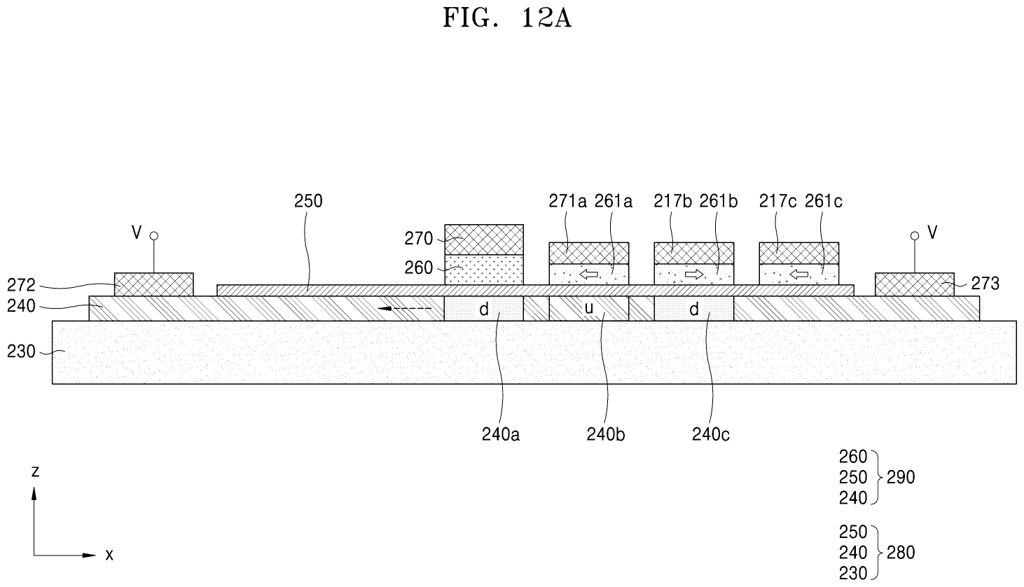

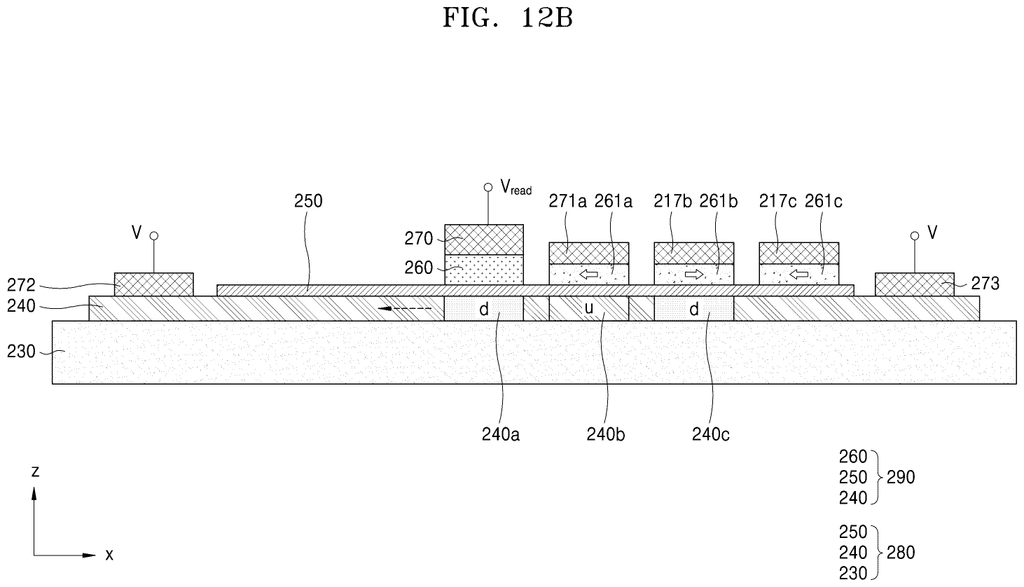

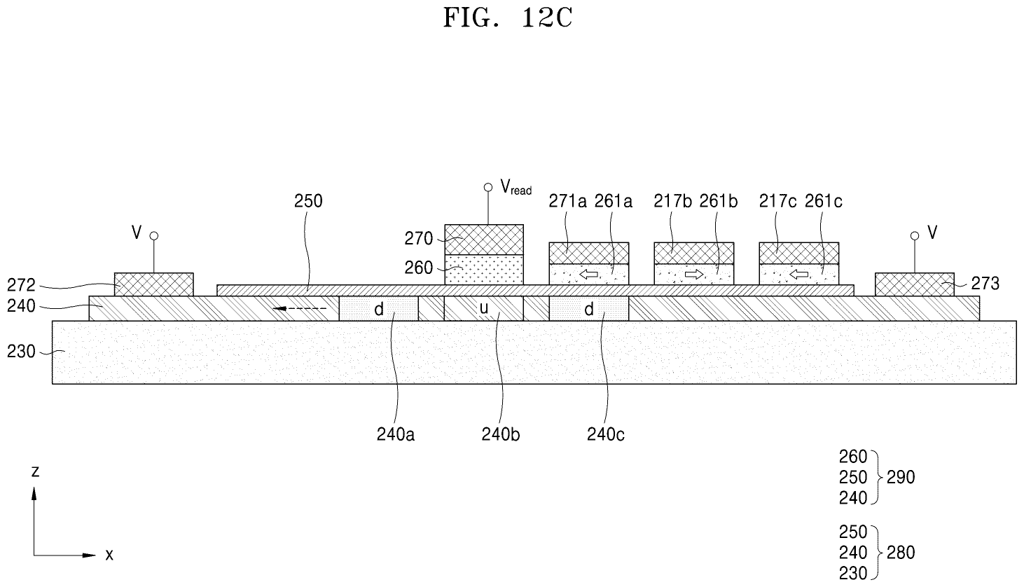

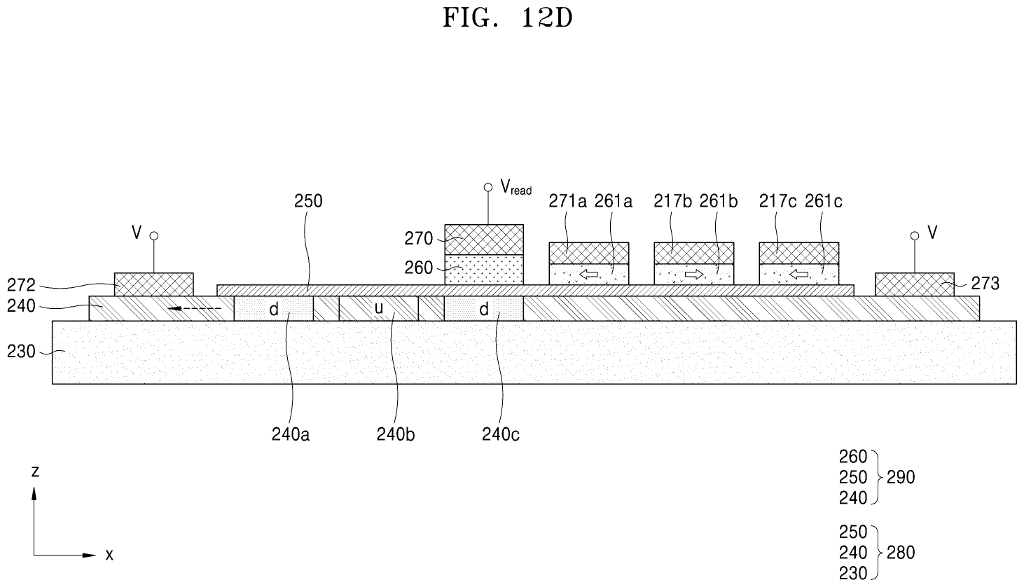

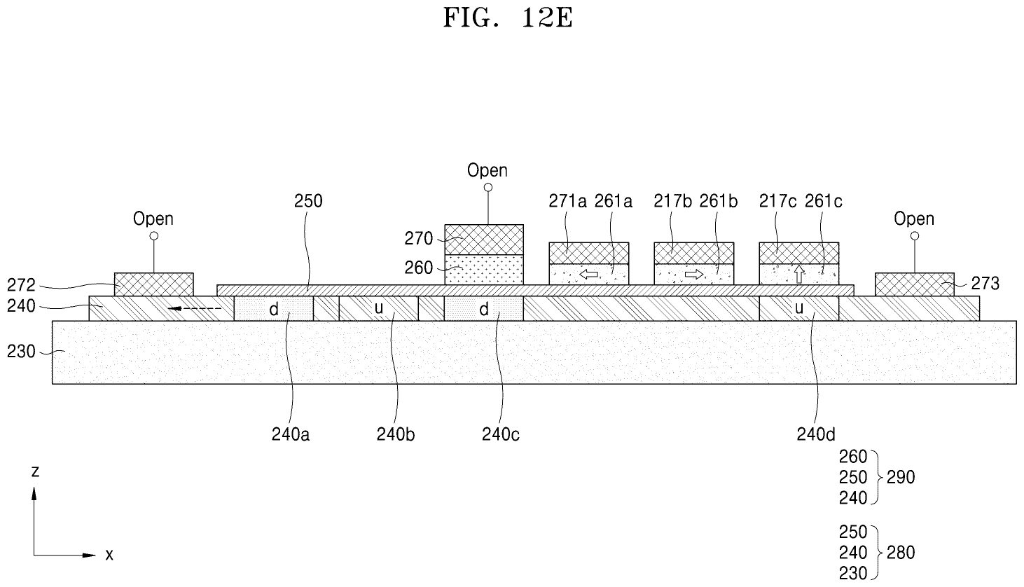

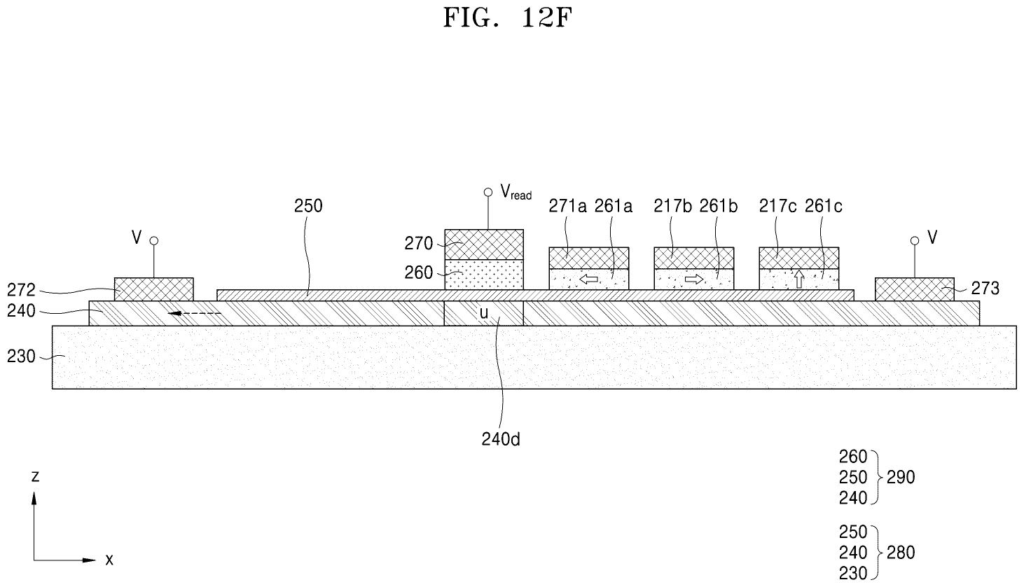

FIGS. 12A to 12D are diagrams illustrating a data reading method of a memory device according to some example embodiments.

Referring to FIG. 12A, after forming a plurality of magnetic domains, a first magnetic domain 240a is moved to overlap the pinned layer 260 in a perpendicular direction (e.g., Z direction). To generate the plurality of magnetic domains, voltages need to be sequentially applied to the second electrode 271a, the third electrode 271b, and the fourth electrode 271c.

Referring to FIG. 12B, the pinned layer 260 may read the first magnetic domain 240a overlapping the pinned layer 260 in the perpendicular direction (e.g., Z direction). A current may be applied to the pinned layer 260 through the first electrode 270. In this regard, at least one of the fifth electrode 272 and the sixth electrode 273 may be grounded, and the second electrode 271a, the third electrode 271b, and the fourth electrode 271c may be opened or may be in an appropriate voltage condition. Data may be read by using a TMR value of a tunneling magnetoresistance layer 290 through the applied current.

Referring to FIG. 12C, a second magnetic domain 240b is moved to overlap the pinned layer 260 in the perpendicular direction (e.g., Z direction) so as to read the second magnetic domain 240b. To move the second magnetic domain 240b, one of the fifth electrode 272 and the sixth electrode 273 may be opened, and a high voltage may be applied to the other electrode. Thereafter, the pinned layer 260 may read the second magnetic domain 240b overlapping the pinned layer 260 in the perpendicular direction (e.g., Z direction). Data may be read by using the TMR value of the tunneling magnetoresistance layer 290.

Referring to FIG. 12D, a third magnetic domain 240c is moved to overlap the pinned layer 260 in the perpendicular direction (e.g., Z direction) so as to read the third magnetic domain 240c. To move the third magnetic domain 240c, one of the fifth electrode 272 and the sixth electrode 273 may be opened, and a high voltage may be applied to the other electrode. Thereafter, the pinned layer 260 may read the third magnetic domain 240c overlapping the pinned layer 260 in the perpendicular direction (e.g., Z direction). Data may be read by using the TMR value of the tunneling magnetoresistance layer 290.

FIGS. 12E and 12F are diagrams for describing a RT-line initializing method of a memory device according to some example embodiments.

Referring to FIG. 12E, a RT-line 280 may be initialized. The first to sixth electrodes 270, 271a, 271b, 271c, 272 and 273 are opened. Thereafter, a fourth magnetic domain 240d is formed by applying a voltage is applied to the fourth electrode 271c and one of the fifth electrode 272 and the sixth electrode 273.

Referring to FIG. 12F, the first to fourth electrodes 270, 271a, 271b and 271c are opened, and the voltage is applied to the fifth electrode 272 and the sixth electrode 273. The fourth magnetic domain 240d extends in a current direction (−X). Current continues to flow until an edge of the generated fourth magnetic domain 240d reaches an end of the RT-line 280. When the fourth magnetic domain 240d reaches the end of the RT-line 280, voltage is blocked from the fifth electrode 272 and the sixth electrode 273. Through the process, a magnetic domain remaining in the RT-line 280 may be removed.

Meanwhile, an arrow direction of each of FIGS. 8A to 8F is one of examples of available directions. The arrow directions shown in FIGS. 8A to 8F are only for illustrating the disclosure and are not limited thereto.

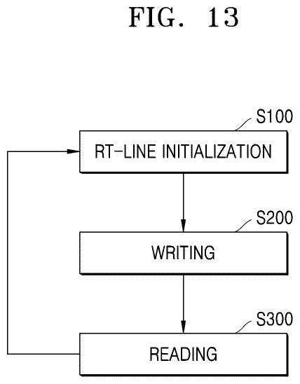

FIG. 13 is a flowchart illustrating an operating method of a memory device according to some example embodiments.

Referring to FIG. 13, the operating method of the memory device according to some example embodiments may be performed in the order of RT-line initialization (S100), data writing (S200), and data reading (S300).

As described with reference to FIGS. 10A to 10E, 12E, and 12F, the RT-line initialization (S100) may be performed by newly forming a magnetic domain and deleting the magnetic domain remaining in a RT-line by applying a voltage so that an edge of the formed magnetic domain reaches an end of the RT-line.

As described with reference to FIGS. 5A to 5G, 7A to 7E, and 8A to 8G, data writing (S200) may be performed by applying a current to a volume change material layer and forming a magnetic domain in a free layer.

As described with reference to FIGS. 9A to 9F and 12A to 12D, data reading (S300) may be performed by reading a magnetic domain overlapping a pinned layer in a perpendicular direction. Reading the magnetic domain means reading a TMR of a tunneling magnetoresistance layer.

In some example embodiments, after data reading (S300) is completed and/or concurrently with data reading (S300) being completed, new data may be written and read by initializing the RT-line again.

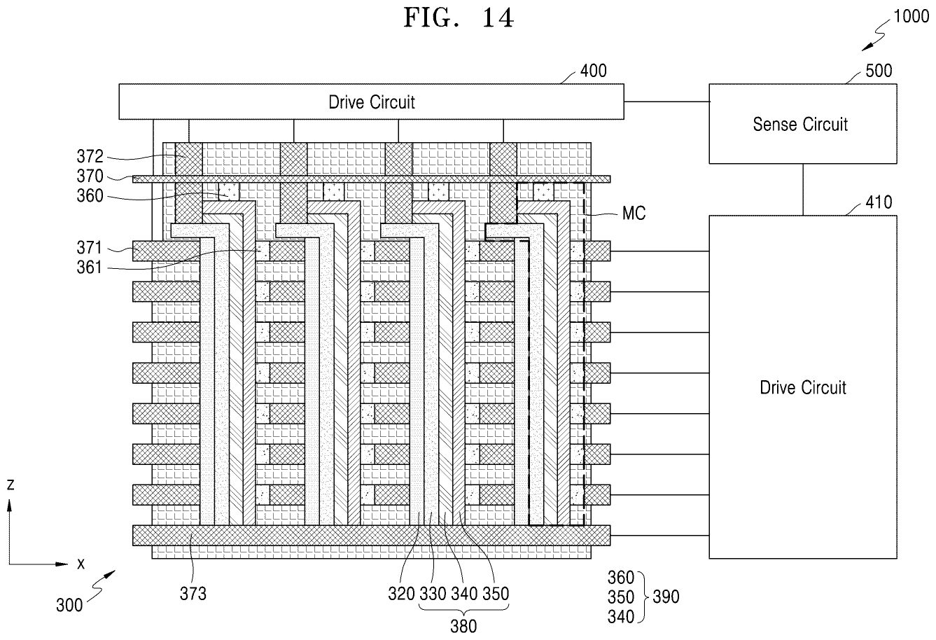

FIG. 14 is a diagram illustrating a memory system 1000 according to some example embodiments.

Referring to FIG. 14, the memory system 1000 may include a memory device 300, a plurality of drive circuits 400 and 410, and a sense circuit 500.

The memory device 300 includes a plurality of memory cells MC, and each of the memory cells MC may include a heavy metal layer 330, a free layer 340, a dielectric layer 350, a pinned layer 360 on the dielectric layer 350 in a perpendicular direction (Z direction), and a plurality of volume change material layers 361 on the dielectric layer 350 in a horizontal direction (X direction), which are sequentially provided. The memory device 300 may include an insulating layer 320 insulating the plurality of memory cells MC, a first electrode 370 connecting the plurality of pinned layers 360 to each other, a second electrode 371 connecting the plurality of memory cells MC to each other and connecting the plurality of memory cells MC to the drive circuit 410, a third electrode 372 connecting the plurality of memory cells MC to the drive circuit 400, and a fourth electrode 373 connecting the plurality of memory cells MC to each other.

The memory device 300 may include the memory device 100 or 200 of FIG. 1 or 11. The heavy metal layer 330, the free layer 340, the dielectric layer 350, the pinned layer 360, the volume change material layers 361, the first electrode 370, the second electrode 371, the third electrode 372, and the fourth electrode 373 may be respectively the same as the heavy metal layers 130 and 230, the free layers 140 and 240, the dielectric layers 150 and 250, the pinned layers 160 and 260, the volume change material layers 161 and 261, the first electrode 170, the second electrode 171, the third electrode 172, and the fourth electrode 173 described with reference to FIGS. 1 and 11. In describing FIG. 14, descriptions redundant with those of FIGS. 1 and 11 are omitted.

The drive circuits 400 and 410 may initialize a RT line 380 of the memory device 300, may be used for data read, and may control a magnetic domain. The sense circuit 500 may measure a TMR value of a tunneling magnetoresistance layer 390 of the memory device 300. The drive circuits 400 and 410 and the sense circuit 500 may be controlled by a controller (not shown).

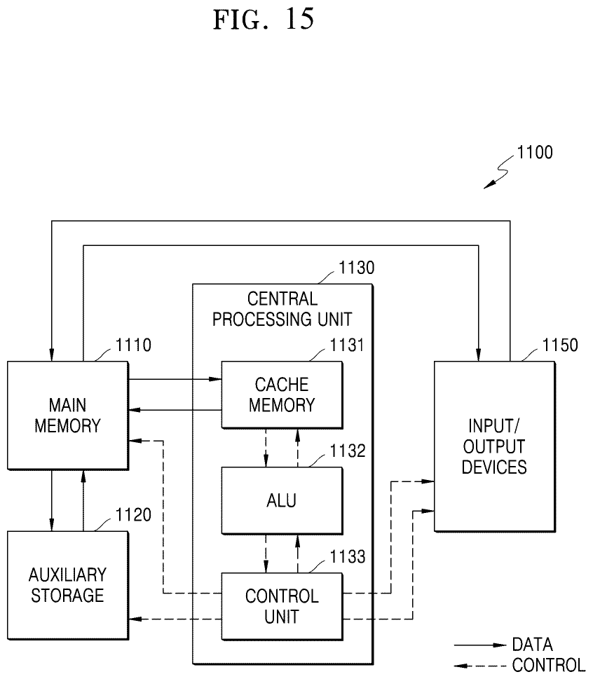

FIG. 15 is a conceptual diagram schematically illustrating a device architecture applicable to an electronic device 1100 according to some example embodiments.

Referring to FIG. 15, the electronic device 1100 may include a main memory 1110, an auxiliary storage 1120, a central processing unit (CPU) 1130, and an input/output device 1150. The CPU 1130 may include a cache memory 1131, an arithmetic logic unit (ALU) 1132, and a control unit 1133. The cache memory 1131 may include static random-access memory (SRAM). The main memory 1110 may include a DRAM device, and the auxiliary storage 1120 may include the memory devices 100, 200, and 300 according to some example embodiments. Alternatively, all of the cache memory 1131, the main memory 1110, and the auxiliary storage 1120 may include the memory devices 100, 200, and 300 according to some example embodiments. In some cases, the electronic device 1100 may be implemented in a form in which computing unit devices and memory unit devices are adjacent to each other in one chip without distinction of the sub-units described above.

According to the memory device and the operating method of the memory device of some example embodiments, the memory device includes a volume change material layer, thereby injecting a magnetic domain into a RT-line through an inverse magnetostrictive effect, and improving stability of the injected magnetic domain.

Alternatively or additionally according to some example embodiments, the memory device and/or the operating method of the memory device may more easily inject the magnetic domain into the RT-line through the inverse magnetostrictive effect.

Alternatively or additionally according to some example embodiments, the memory device including the volume change material layer and the memory system including the memory device have improved stability of the injected magnetic domain.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc.

The processing circuitry may include electrical components such as logic gates including at least one of AND gates, OR gates, NAND gates, NOT gates, etc.

It should be understood that some example embodiments described herein should be considered in a descriptive sense only and not for purposes of limitation.

Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A memory device comprising:
a heavy metal layer;
a free layer on the heavy metal layer;
a dielectric layer on the free layer; and
a pinned layer and a volume change material layer on the dielectric layer and spaced apart from each other,
wherein the dielectric layer comprises an oxide comprising magnesium (Mg).

2. The memory device of claim 1, wherein the volume change material layer includes a ferroelectric material or a piezoelectric material.

3. The memory device of claim 1, wherein the volume change material layer includes at least one of HfO₂, Hf₁₋ₓZrₓO₂(1<x<0), Hf₁₋ₓAlₓO₂(1<x<0), BaTiO₃, or PbZr₁₋ₓTiₓO₃(1<x<0).

4. The memory device of claim 1, wherein the volume change material layer includes at least one of GaN, InN, AlN, BaTiO₃, PbZr₁₋ₓTiₓO₃(1<x<0), BiFeO₃, or ZnO.

5. The memory device of claim 1, wherein the heavy metal layer includes at least one of iridium (Ir), ruthenium (Ru), tantalum (Ta), platinum (Pt), palladium (Pd), bismuth (Bi), titanium (Ti), tungsten (W), or an alloy thereof.

6. The memory device of claim 1, wherein the free layer includes cobalt (Co).

7. The memory device of claim 1, wherein the free layer has a synthetic anti-ferromagnetic (SAF) structure.

8. The memory device of claim 7, wherein the free layer includes a first ferromagnetic layer, a non-magnetic layer, and a second ferromagnetic layer which are sequentially stacked.

9. The memory device of claim 8, wherein the first ferromagnetic layer includes a multilayer structure.

10. The memory device of claim 9, wherein
the first ferromagnetic layer includes at least one of a multilayer structure of Co, Ni, and Co which are sequentially stacked, a multilayer structure of Co, Pt, and Co which are sequentially stacked, or a multilayer structure of Co, Ir, and Co which are sequentially stacked,
the non-magnetic layer includes at least one of Ru or Ir, and
the second ferromagnetic layer includes a single layer of CoFeB or includes first to third layers which are sequentially stacked, the first layer including at least one of Co or CoFe, the second layer including W or Ta, and the third layer including at least one of CoFeB or FeB.

11. The memory device of claim 1, further comprising:
a first electrode on the pinned layer.

12. The memory device of claim 11, wherein the first electrode includes at least one of TiN or Au.

13. The memory device of claim 11, further comprising:
a second electrode on the volume change material layer.

14. The memory device of claim 13, wherein the second electrode includes TiN.

15. The memory device of claim 1, further comprising:
a third electrode and a fourth electrode spaced apart from each other on the free layer.

16. A memory device comprising:
a heavy metal layer;
a free layer on the heavy metal layer;
a dielectric layer on the free layer;
a pinned layer on the above dielectric layer and corresponding to a magnetic tunnel junction (MTJ) structure with the free layer and the dielectric layer; and
a plurality of volume change material layers on the dielectric layer and configured to inject magnetic domains into the free layer,
wherein the dielectric layer comprises an oxide comprising magnesium (Mg).

17. The memory device of claim 16, wherein the plurality of volume change material layers each independently includes a ferroelectric material or a piezoelectric material.

18. The memory device of claim 16, wherein the plurality of volume change material layers each independently includes at least one of HfO₂, Hf₁₋ₓZrₓO₂, Hf₁₋ₓAlₓO₂, BaTiO₃, or PbZr₁₋ₓTiₓO₃(1<x<0).

19. The memory device of claim 16, wherein the plurality of volume change material layers each independently includes at least one of GaN, InN, AlN, BaTiO₃, PbZr₁₋ₓTiₓO₃(1<x<0), BiFeO₃, or ZnO.

20. An operating method of a memory device comprising
a heavy metal layer,
a free layer on the heavy metal layer,
a dielectric layer on the free layer, comprising an oxide comprising magnesium (Mg), and corresponding to a racetrack (RT)-line with the heavy metal layer and the free layer, and
a pinned layer and a volume change material layer on the dielectric layer and spaced apart from each other, the operating method comprising:
initializing the RT-line;
forming a magnetic domain in the free layer by applying a current to the volume change material layer; and
reading the magnetic domain overlapping the pinned layer in a perpendicular direction.
